(19) United States
(12) Patent Application Publication
(10) Pub. No.: US 2016/0172532 A1
(43) Pub. Date: Jun. 16, 2016

(54) METHOD OF MANUFACTURING SEMICONDUCTOR LIGHT-EMITTING DEVICE

(71) Applicant: Samsung Electronics Co., Ltd., Suwon-si (KR)

(72) Inventors: Do-young RHEE, Seoul (KR); Bum-joon KIM, Seoul (KR); Suk-ho YOON, Seoul (KR); Keon-hun LEE, Seoul (KR); Kee-won LEE, Suwon-si (KR); Sang-don LEE, Suwon-si (KR)

(21) Appl. No.: 14/965,894

(22) Filed: Dec. 10, 2015

(30) Foreign Application Priority Data
Dec. 12, 2014 (KR) 10-2014-0179350

(51) Int. Cl. H01L 33/00; H01L 33/24

(52) U.S. Cl. CPC H01L 33/0075; H01L 33/24

(57) ABSTRACT

A method of manufacturing a semiconductor light-emitting device is provided. The method includes operations of forming a first conductive type semiconductor layer on a substrate; forming a V-pit in the first conductive type semiconductor layer; forming a defect decreasing structure in and over the V-pit; and forming a residual first conductive type semiconductor layer on the defect decreasing structure. By using the method, an excellent-quality semiconductor light-emitting device having a reduced crystal defect may be inexpensively manufactured.

### CROSS-REFERENCE TO RELATED APPLICATION

This application claims the benefit of Korean Patent Application No. 10-2014-0179350, filed on Dec. 12, 2014, in the Korean Intellectual Property Office, the disclosure of which is incorporated herein in its entirety by reference.

### BACKGROUND

The inventive concept relates to a method of manufacturing a semiconductor light-emitting device, and more particularly, to a method of inexpensively manufacturing an excellent-quality semiconductor light-emitting device having a reduced crystal defect.

A semiconductor light-emitting device is a semiconductor device that generates light of various colors at a junction between first and second conductive semiconductors based on recombination of electrons and holes in response to a current applied thereto. Compared to a filament-based light-emitting device, the semiconductor light-emitting device has many advantages such as long lifetime, lower power consumption, excellent initial drive characteristic, etc. Thus, the need for semiconductor light-emitting devices has constantly increased. In particular, recently, a group-III nitride semiconductor capable of emitting blue light in a short-wavelength region has been highlighted.

In general, a semiconductor light-emitting device has a structure including an active layer disposed between first and second conductive type semiconductor layers. However, since a crystal quality of a lower semiconductor layer affects crystal qualities of other layers formed on the lower semiconductor layer, and an emission characteristic is affected by the crystal quality, there is a constant demand for improving the crystal quality.

### SUMMARY

The inventive concept provides a method of inexpensively manufacturing an excellent-quality semiconductor light-emitting device having a reduced crystal defect.

According to an aspect of the inventive concept, a method is provided for manufacturing a semiconductor light-emitting device. The method includes forming a first conductive type semiconductor layer on a substrate; forming a V-pit in the first conductive type semiconductor layer; forming a defect decreasing structure in and over the V-pit; and forming a residual first conductive type semiconductor layer on the defect decreasing structure.

The defect decreasing structure may be a mesa-shape structure or a pyramid-shape structure. When the defect decreasing structure is the pyramid-shape structure, the pyramid-shape structure may include silicon (Si). Here, a density of Si in the pyramid-shape structure may be 5×10¹⁷ cm⁻³ through 1×10²⁰ cm⁻³.

The operation of forming the defect decreasing structure may be performed under at least one condition of (i) a higher pressure, (ii) a higher growth rate, and (iii) a lower (group-V source material)/(group-III source material) molar ratio, compared to the operation of forming the first conductive type semiconductor layer that is performed before the operation of forming the defect decreasing structure.

Here, (i) the higher pressure may indicate a pressure of 70 millibars (mb) through 1 atmosphere (atm), (ii) the higher growth rate may indicate a growth rate of 1.5 Å/sec. through 85 Å/sec, and (iii) the lower (group-V source material)/(group-III source material) molar ratio may be 20 through 400.

The first conductive type semiconductor layer may be a group III-V semiconductor layer, and the operation of forming the V-pit may include operations of stopping supplying a group-III source material to the first conductive type semiconductor layer; and supplying a silicon (Si) source material to the first conductive type semiconductor layer.

After the operation of forming the residual first conductive type semiconductor layer, the method may further include operations of forming an active layer on the residual first conductive type semiconductor layer; and forming a second conductive type semiconductor layer on the active layer.

According to another aspect of the inventive concept, a method is provided for manufacturing a semiconductor light-emitting device. The method includes supplying a group-III source material and a group-V source material onto a substrate so as to form a first conductive type semiconductor layer on the substrate; stopping supplying the group-III source material, and supplying a silicon (Si) source material so as to form a V-pit in the first conductive type semiconductor layer; supplying the group-III source material to the V-pit so as to form a defect decreasing structure in and over the V-pit; and supplying the group-III source material and the group-V source material so as to form a residual first conductive type semiconductor layer on the defect decreasing structure.

The operation of supplying the group-III source material so as to form the defect decreasing structure in the V-pit may include an operation of supplying the group-III source material without supplying the silicon (Si) source material so as to form a mesa-shape defect decreasing structure.

The operation of supplying the group-III source material so as to form the defect decreasing structure in the V-pit may include an operation of supplying the silicon (Si) source material so as to form a pyramid-shape defect decreasing structure.

The silicon (Si) source material may be silane (SiH₄).

In the operation of supplying the group-III source material so as to form the defect decreasing structure in the V-pit, the group-III source material may be at least one material selected from the group consisting of an aluminum (Al) source material, an indium (In) source material, and a gallium (Ga) source material.

According to another aspect, a method of manufacturing a semiconductor light-emitting device is provide. The method comprises forming a first conductive type semiconductor layer on a substrate; forming a plurality of V-pits in a top surface of the first conductive type semiconductor layer wherein each of the plurality of V-pits has a first slope; forming a plurality of defect decreasing structures in corresponding ones of the plurality of V-pits such that each of the plurality of defect decreasing structures above the top surface of the first conductive type semiconductor layer has a second slope different from the first slope of a corresponding one of the plurality of V-pits; and forming a residual first conductive type semiconductor layer on the plurality of defect decreasing structures.

In one embodiment, the plurality of the V-pits are separated from each other or partially overlapped with each other.

In another embodiment, the plurality of defect decreasing structures have a composition of AlₓIn_{y}Ga_{(1-x-y)}N (0≦x≦1, 0≦y≦1, 0≦x+y≦1) and forming the plurality of defect decreasing structures includes supplying a group-III source material and a group-V source material.

In another embodiment, the plurality of defect decreasing structures are formed under a condition where one of a pressure, a growth rate of the plurality of defect decreasing structures and a molar ratio of (group-V source material)/(group-III source material) is different from that in the forming the first conductive type semiconductor layer.

In another embodiment, each of the first conductive type semiconductor layer and the residual first conductive type semiconductor layer has a thickness of 10 nm through 5000 nm.

### BRIEF DESCRIPTION OF THE DRAWINGS

Exemplary embodiments of the inventive concept will be more clearly understood from the following detailed description taken in conjunction with the accompanying drawings in which:

FIG. 1 is a flowchart that illustrates a method of growing a semiconductor material layer, according to an exemplary embodiment;

FIGS. 2A through 2D are cross-sectional side views that sequentially illustrate the method of growing a semiconductor material layer, according to an exemplary embodiment;

FIGS. 3A and 3B are cross-sectional side views that illustrate a method of growing a semiconductor material layer, according to another exemplary embodiment;

FIGS. 4A through 4C are cross-sectional side views that sequentially illustrate a method of manufacturing a semiconductor light-emitting device, according to an exemplary embodiment;

FIG. 5 is a cross-sectional side view that illustrates a semiconductor light-emitting device, according to another exemplary embodiment;

FIGS. 6 through 8 are cross-sectional side views that illustrate light-emitting devices, according to exemplary embodiments;

FIGS. 9 and 10 are cross-sectional side views that illustrate light-emitting packages, according to exemplary embodiments;

FIG. 11 illustrates a color temperature spectrum related to light that is emitted from the light-emitting device, according to an exemplary embodiment;

FIG. 12 illustrates an example of a structure of a quantum dot (QD) that may be used in the light-emitting device, according to an exemplary embodiment;

FIG. 13 illustrates phosphor types according to application fields of a white light-emitting apparatus using a blue light-emitting device, according to an exemplary embodiment;

FIG. 14 is an exploded perspective view that illustrates a direct-type backlight assembly including a light-emitting device array of light-emitting diode (LED) chips, which is manufactured by using the method of manufacturing a semiconductor light-emitting device, according to an exemplary embodiment;

FIG. 15 illustrates a flat panel semiconductor light-emitting apparatus including a light-emitting device array of LED chips and a light-emitting device module, which are manufactured by using the method of manufacturing a semiconductor light-emitting device, according to an exemplary embodiment;

FIG. 16 illustrates a bulb type lamp as a semiconductor light-emitting apparatus including a light-emitting device array of LED chips and a light-emitting device module, which are manufactured by using the method of manufacturing a semiconductor light-emitting device, according to an exemplary embodiment; and

FIGS. 17 and 18 illustrate a home network to which a lighting system using a light-emitting device is applied, according to an exemplary embodiment.

### DETAILED DESCRIPTION OF THE EMBODIMENTS

The inventive concept will now be described more fully with reference to the accompanying drawings, in which exemplary embodiments of the inventive concept are shown. The inventive concept may, however, be embodied in many different forms and should not be construed as being limited to the embodiments set forth herein; rather, these embodiments are provided so that this disclosure will be thorough and complete, and will fully convey the inventive concept to those of ordinary skill in the art. In the drawings, similar reference numerals denote similar configuring elements, and the thicknesses of layers and regions are exaggerated for clarity.

While terms “first” and “second” are used to describe various components, it is obvious that the components are not limited to the terms “first” and “second”. The terms “first” and “second” are used only to distinguish between each component. For example, a first component may indicate a second component or a second component may indicate a first component without conflicting with the inventive concept.

Furthermore, all examples and conditional language recited herein are to be construed as being without limitation to such specifically recited examples and conditions. Throughout the specification, a singular form may include plural forms, unless there is a particular description contrary thereto. Also, terms such as “comprise” or “comprising” are used to specify existence of a number, an operation, a component, and/or groups thereof, not excluding the existence of one or more other numbers, one or more other operations, one or more other components and/or groups thereof.

Unless expressly described otherwise, all terms including descriptive or technical terms which are used herein should be construed as having meanings that are obvious to one of ordinary skill in the art. Also, terms that are defined in a general dictionary and that are used in the following description should be construed as having meanings that are equivalent to meanings used in the related description, and unless expressly described otherwise herein, the terms should not be construed as being ideal or excessively formal.

As used herein, the term “and/or” includes any and all combinations of one or more of the associated listed items. Expressions such as “at least one of” when preceding a list of elements, modify the entire list of elements and do not modify the individual elements of the list.

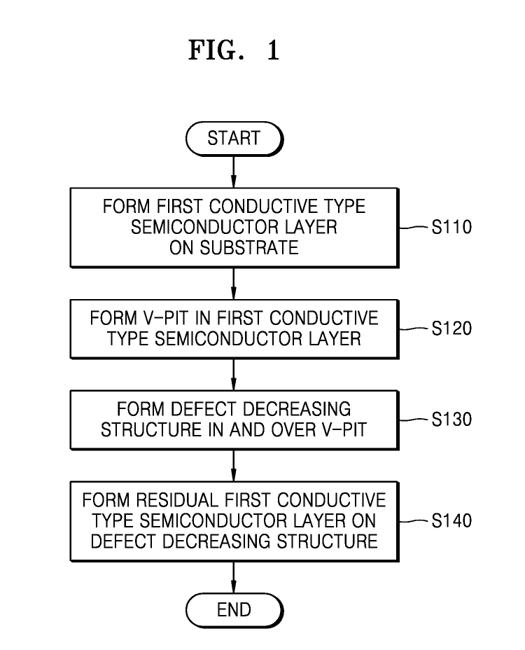

FIG. 1 illustrates a flowchart of a method of growing a semiconductor material layer, according to an exemplary embodiment.

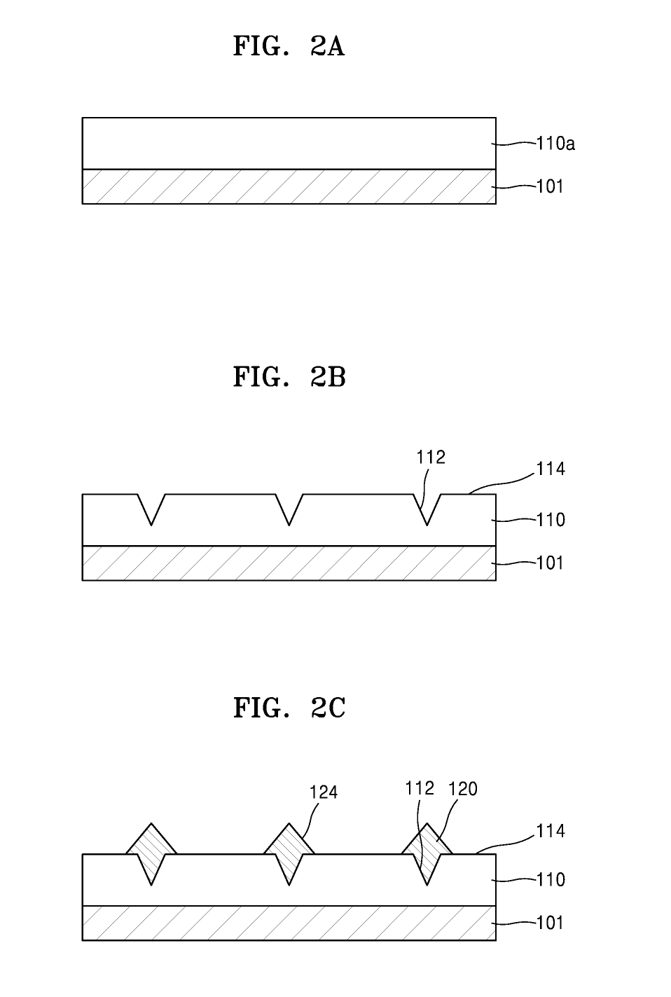

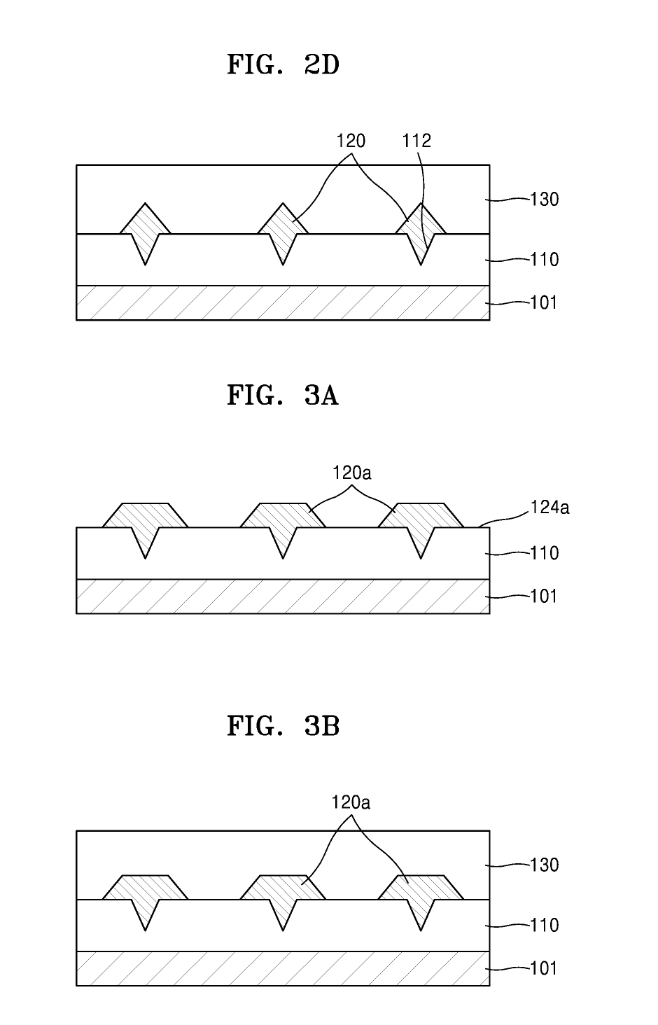

FIGS. 2A through 2D are cross-sectional side views that sequentially illustrate the method of growing a semiconductor material layer.

Referring to FIGS. 1 and 2A, a first conductive type semiconductor layer 110a may be formed on a substrate 101 (S110).

The substrate 101 may be disposed below the first conductive type semiconductor layer 110a and thus may support the first conductive type semiconductor layer 110a. The substrate 101 may receive heat from the first conductive type semiconductor layer 110a and may externally radiate the received heat. Also, the substrate 101 may have a light-transmittance characteristic. If the substrate 101 is formed of a light-transmissive material or has a thickness equal to or less than a predetermined value, the substrate 101 may have the light-transmittance characteristic. In order to increase a light extraction efficiency, the substrate 101 may have a refractive index that is less than that of the first conductive type semiconductor layer 110a. The substrate 101 will be described in detail at a later time.

The first conductive type semiconductor layer 110a may be a semiconductor layer including n-type or p-type impurities. Alternatively, the first conductive type semiconductor layer 110a may be formed of a group III-V semiconductor, e.g., a group-III nitride semiconductor. Further, the first conductive type semiconductor layer 110a may be formed of a material having the composition of AlₓIn_{y}Ga_{(1-x-y)}N (0≦x≦1, 0≦y≦1, 0≦x+y≦1). However, one or more exemplary embodiments are not limited thereto, and in another exemplary embodiment, the first conductive type semiconductor layer 110a may be formed of a material including an AlGaInP-based semiconductor, an AlGaAs-based semiconductor, or the like.

The first conductive type semiconductor layer 110a may be grown by using a metal organic chemical vapor deposition (MOCVD) process, a hydride vapor phase epitaxy (HYPE) process, a molecular beam epitaxy (MBE) process, or an atomic layer deposition (ALD) process, but one or more exemplary embodiments are not limited thereto.

In a case where the first conductive type semiconductor layer 110a is formed of the group III-V semiconductor, a group-III source material and a group-V source material may be provided onto the substrate 101. For example, the group-III source material may be at least one material selected from the group consisting of an aluminum (Al) source material, an indium (In) source material, and a gallium (Ga) source material.

The Al source material may be, but is not limited to, at least one material selected from the group consisting of trimethylaluminum, triethylaluminum, tris(dimethylamide)aluminum, triisobutylaluminum, aluminum tris(2,2,6,6-tetramethyl-3,5-heptanedionate), AlMe₂H, [Al(OsBu)₃]₄, Al(CH₃COCHCOCH₃)₃, AlCl₃, AlBr₃, AlI₃, Al(OiPr)₃, [Al(NMe₂)₃]₂, Al(iBu)₂Cl, Al(iBu)₃, Al(iBu)₂H, AlEt₂Cl, Et₃Al₂(OsBu)₃, Al(THD)₃, H₃AlNMe₃, H₃AlNEt₃, H₃AlNMe₂Et, and H₃AlMeEt₂.

The In source material may be, but is not limited to, at least one material selected from the group consisting of trimethylindium, triethylindium, triisopropylindium, tributylindium, tritertiarybutylindium, trimethoxyindium, triethoxyindium, triisopropoxyindium, dimethylisopropoxyindium, diethylisopropoxyindium, dimethylethylindium, diethylmethylindium, dimethylisopropylindium, diethylisopropylindium, and dimethyl-tert-butylindium.

The Ga source material may be trimethylgallium (TMG), triethylgallium (TEG), or diethylgallium chloride.

The group-V source material may be a nitrogen source including, but is not limited to, ammonia (NH₃), nitrogen (N₂), or plasma-excited species of ammonia and/or nitrogen.

The first conductive type semiconductor layer 110a may be a single layer having one composition or may be multiple layers formed of at least two stacked layers having different compositions.

Referring to FIGS. 1 and 2B, a V-pit 112 may be formed in the first conductive type semiconductor layer 110. The V-pit 112 may be formed in a top surface 114 of the first conductive type semiconductor layer 110. In particular, the V-pit 112 may be formed by partially etching the top surface 114 of the first conductive type semiconductor layer 110a and removing a region of the top surface of the first conductive type semiconductor layer 110a.

In order to partially etch the top surface of the first conductive type semiconductor layer 110a and to remove the region of the top surface of the first conductive type semiconductor layer 110a, a silane (SiH₄) gas may be supplied, as a silicon (Si) source, onto the top surface of the first conductive type semiconductor layer 110a. In particular, a thermal treatment may be performed in a mixed gas atmosphere containing SiH₄, the group-V source material, and hydrogen (H₂), so that the V-pit 112 may be formed in the top surface of the first conductive type semiconductor layer 110. The group-V source material may be, but is not limited to, ammonia (NH₃), nitrogen (N₂), or plasma-excited species of ammonia and/or nitrogen. The thermal treatment may be performed at a temperature of 600 through 1,000° C.

Here, if the group-III source material is supplied onto the first conductive type semiconductor layer 110a, the V-pit 112 may not be formed. Thus, the group-III source material is not supplied. Although it is previously described that the group-III source material is supplied to a process of forming the first conductive type semiconductor layer 110a, the supply of the group-III source material may be stopped while the V-pit 112 is formed.

Referring to FIG. 2B, a plurality of the V-pits 112 are separated from each other, but in another exemplary embodiment, the V-pits 112 may partially overlap with each other.

A plurality of threading dislocations exist in the first conductive type semiconductor layer 110 in which the V-pits 112 are formed. While the first conductive type semiconductor layer 110a of FIG. 2A grows, the threading dislocations may be combined with each other or may disappear, so that a threading dislocation density (TDD) indicating the number of threading dislocations in a unit area may be decreased.

However, some threading dislocations that extend to the top surface of the first conductive type semiconductor layer 110 may reach slopes of the V-pits 112.

Referring to FIGS. 1 and 2C, defect decreasing structures 120 may be formed in and over the V-pits 112 (S130)

The defect decreasing structures 120 may be formed to correspond to the V-pits 112, respectively. Each of the defect decreasing structures 120 may have a pyramid shape. The pyramid shape may refer to a portion of the defect decreasing structure 120 that is formed above the top surface 114 of the first conductive type semiconductor layer 110. A slope of a side wall 124 of the pyramid shape defect decreasing structures 120 may be varied depending on the condition of the defect decreasing structure formation. The defect decreasing structure 120 may have the composition of AlₓIn_{y}Ga_{(1-x-y)}N (0≦x≦1, 0≦y≦1, 0≦x+y≦1).

In order to form the defect decreasing structure 120, a group-III source material and a group-V source material may be supplied. The group-III source material may be at least one material selected from the group consisting of an Al source material, an In source material, and a Ga source material. The group-V source material may be NH₃. However, one or more exemplary embodiments are not limited thereto. Examples of the Al source material, the In source material, and the Ga source material are described above, and thus are omitted here.

Also, a silicon source material may be further supplied to a process of forming the defect decreasing structure 120 having the pyramid shape. The silicon source material may be, but is not limited to, SiH₄. A density of the silicon source material may be adjusted in such a manner that a doped silicon density in the defect decreasing structure 120 may be maintained at a high density. The doped silicon density in the defect decreasing structure 120 may be 5×10¹⁷ cm⁻³ through 1×10²⁰ cm⁻³. If the doped silicon density is too low, lateral growth is not suppressed such that the defect decreasing structure 120 having the pyramid shape may not be formed. On the other hand, if the doped silicon density is too high, a material property of the material layer finally obtained may deteriorate, and a possibility of abnormal growth at the top surface may be increased.

The defect decreasing structure 120 may be manufactured under a condition of (i) a higher pressure, (ii) a higher growth rate of the defect decreasing structure, and/or (iii) a lower (group-V source material)/(group-III source material) molar ratio, compared to a process of forming the first conductive type semiconductor layer 110 that is formed before the defect decreasing structure 120. In some embodiments, the defect decreasing structures are formed under a condition where one of a pressure, a growth rate of the plurality of defect decreasing structures and a molar ratio of (group-V source material)/(group-III source material) is different from that in the forming the first conductive type semiconductor layer.

First, the defect decreasing structure 120 may be formed with a pressure of 70 millibars (mb) through 1 atmosphere (atm). If the pressure is too low, lateral growth of the defect decreasing structure 120 is not suppressed, such that the defect decreasing structure 120 having the pyramid shape may not be formed. On the other hand, if the pressure is too high, a crystal quality of the defect decreasing structure 120 may deteriorate.

Also, the defect decreasing structure 120 may be formed with a growth rate of 1.5 Å/sec. through 85 Å/sec. If the growth rate of the defect decreasing structure 120 is too low, the lateral growth of the defect decreasing structure 120 is not suppressed, such that the defect decreasing structure 120 having the pyramid shape may not be formed. On the other hand, if the growth rate of the defect decreasing structure 120 is too high, the crystal quality of the defect decreasing structure 120 may deteriorate, and point defects of the defect decreasing structure 120 may be increased.

Also, the defect decreasing structure 120 may be formed at a condition where a value of a (group-V source material)/(group-III source material) molar ratio is 20 through 400. If the (group-V source material)/(group-III source material) molar ratio is too low, the crystal quality may deteriorate. On the other hand, if the (group-V source material)/(group-III source material) molar ratio is too high, the lateral growth of the defect decreasing structure 120 is not suppressed, such that the defect decreasing structure 120 having the pyramid shape may not be formed.

Threading dislocations that contact slopes of the V-pit 112 may change their propagation direction, thus bending at an interface between the V-pit 112 and the defect decreasing structure 120 so as to achieve better combination (primary bending). For example, when the threading dislocations that propagate in a direction that is perpendicular from or is almost perpendicular from the top surface of the first conductive type semiconductor layer 110 contact the slopes, the propagation direction of the threading dislocations may change their direction and be bent toward a center of the V-pit 112. As a result, the threading dislocations are gathered at the center of the V-pit 112 and are more likely to be combined with each other. Overall, a density of the plurality of threading dislocations may be decreased.

Referring to FIGS. 1 and 2D, a residual first conductive type semiconductor layer 130 may be formed on the defect decreasing structure 120 (S140). The residual first conductive type semiconductor layer 130 may be equal to or different from the first conductive type semiconductor layer 110 that is formed before the defect decreasing structure 120 is formed. This feature will be described in detail at a later time.

A propagation direction of threading dislocations that contact an interface between the defect decreasing structure 120 and the residual first conductive type semiconductor layer 130 may change at the interface (secondary bending). In particular, the propagation direction of the threading dislocations may change at the interface in such a direction that the threading dislocations are distant from the defect decreasing structure 120. Here, the threading dislocations may be combined with threading dislocations that propagate after being bent at the neighboring defect decreasing structure 120. Alternatively, the threading dislocations may be combined with the threading dislocations that propagate in the direction that is perpendicular from or is almost perpendicular from the top surface of the first conductive type semiconductor layer 110. As a result, the density of the plurality of threading dislocations may be further decreased.

By doing so, the semiconductor material layer having the decreased density of the threading dislocations may be formed on the substrate 101. As described above, the substrate 101 is not removed, but in some exemplary embodiments, the substrate 101 may be removed any time after the first conductive type semiconductor layer 110a is formed (refer to FIG. 2A). A method of removing the substrate 101 may include, but is not limited to, a laser lift off (LLO) method using a laser, an etching method, a grinding method, or the like.

FIGS. 3A and 3B are cross-sectional side views that illustrate a method of growing a semiconductor material layer, according to another exemplary embodiment.

Referring to FIG. 3A, as described above with reference to FIGS. 2A and 2B, the first conductive type semiconductor layer 110 is formed on the substrate 101, and the V-pit 112 is formed in the top surface of the first conductive type semiconductor layer 110. Since the descriptions thereof are previously provided, additional descriptions are not provided here.

Afterward, a defect decreasing structure 120a having a mesa shape may be formed in and over the V-pit 112. The mesa shape may refer to a portion of the defect decreasing structure 120a that is formed above the top surface 114 of the first conductive type semiconductor layer 110. A slope of a side wall 124a of the mesa shape defect decreasing structures 120a may be varied depending on the conditions of the defect decreasing structure formation. A plurality of the defect decreasing structures 120a may be formed while corresponding to the V-pits 112, respectively.

A method of forming the defect decreasing structure 120a is different from the method described with reference to FIG. 2C, in that a silicon source material is not supplied to a process of forming the defect decreasing structure 120a. If the silicon source material is not supplied to the process, suppression of a lateral growth is significantly decreased so that the defect decreasing structure 120a having the mesa shape may be formed as shown in FIG. 3A.

Other processes are same as the processes described above with reference to FIGS. 2A through 2C, thus, additional descriptions thereof are omitted here.

Referring to FIG. 3B, the residual first conductive type semiconductor layer 130 is formed on the defect decreasing structure 120a having the mesa shape. Threading dislocations after primary bending propagate while the threading dislocations pass through the defect decreasing structure 120a in a direction from a bottom toward a top. Here, the propagation direction is changed due to the primary bending, thus, some threading dislocations are combined with each other, so that a density of the threading dislocations is decreased.

Also, when threading dislocations pass through slopes of the defect decreasing structure 120a, secondary bending occurs. The threading dislocations that are secondarily bent while passing through the slopes may be distant from the defect decreasing structure 120a. Here, the threading dislocations may be combined with threading dislocations that propagate after being bent at the neighboring defect decreasing structure 120. Alternatively, the threading dislocations may be combined with threading dislocations that propagate in a direction that is perpendicular from or is almost perpendicular from the top surface of the first conductive type semiconductor layer 110. As a result, a density of the plurality of threading dislocations may be further decreased.

It should be appreciated that a defect decreasing structure may not be limited to a pyramid shape or a masa shape. For example, the defect decreasing structure of the present application may have any other shapes as long as the slope or the interface thereof can change the propagation direction of the threading dislocations within the spirit and scope of the present application. In some embodiments, a V-pit may be formed to have a first slope and a portion of the defect decreasing structure above the top surface of the first conductive type semiconductor may have a second slope. In another embodiment, the first slope may be different from the second slope. In some embodiments, the portion of the defect decreasing structure above the top surface of the first conductive type semiconductor may have a curved surface.

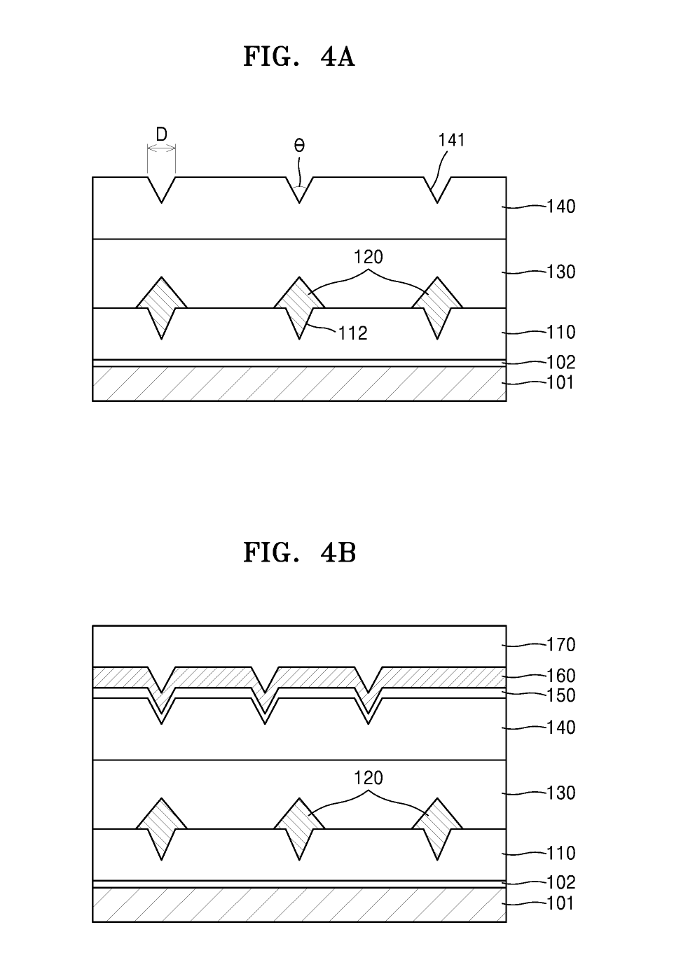

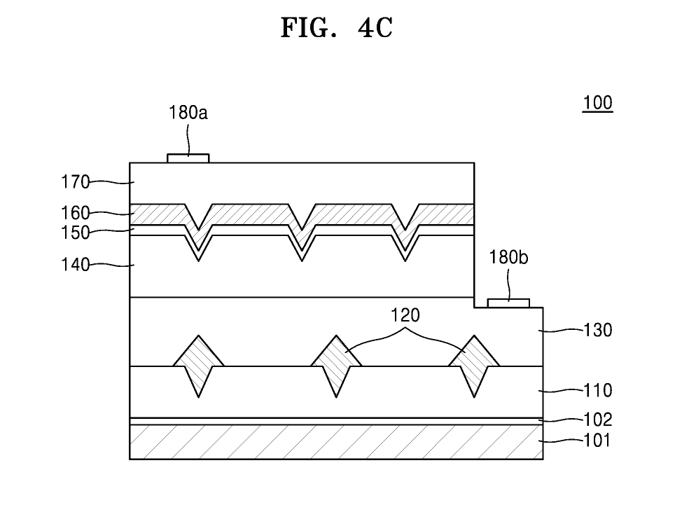

FIGS. 4A through 4C are cross-sectional side views that sequentially illustrate a method of manufacturing a semiconductor light-emitting device 100, according to an exemplary embodiment.

Referring to FIG. 4A, the first conductive type semiconductor layer 110 and the residual first conductive type semiconductor layer 130 are formed on the substrate 101. As described above with reference to FIGS. 2A through 2D, the defect decreasing structure 120 may be disposed in the first conductive type semiconductor layer 110 and the residual first conductive type semiconductor layer 130. A plurality of the defect decreasing structures 120 may be formed in and over the first conductive type semiconductor layer 110 having the V-pits 112 so as to correspond to the V-pits 112, respectively. Afterward, the residual first conductive type semiconductor layer 130 may be formed to cover the defect decreasing structure 120.

If required, the substrate 101 may be formed as an insulating substrate, a conductive substrate, or a semiconductor substrate. For example, the substrate 101 may include sapphire (Al₂O₃), gallium nitride (GaN), silicon (Si), germanium (Ge), gallium-arsenide (GaAs), zinc oxide (ZnO), silicon germanium (SiGe), silicon carbide (SiC), gallium oxide (Ga₂O₃), lithium gallium oxide (LiGaO₂), lithium aluminum oxide (LiAlO₂), or magnesium aluminum oxide (MgAl₂O₄). For an epitaxial growth of a GaN material, it is preferable to use a GaN substrate that is a homogeneous substrate; however, the GaN substrate has a high production cost due to difficulty in its manufacture.

An example of a heterogeneous substrate includes a sapphire substrate, a silicon carbide (SiC) substrate, a silicon substrate, or the like, and in this regard, the sapphire substrate or the silicon substrate is used more than the SiC substrate, which is expensive. When the heterogeneous substrate is used, a defect such as dislocation or the like is increased due to a difference between lattice constants of a substrate material and a thin-film material. Also, due to a difference between thermal expansion coefficients of the substrate material and the thin-film material, the substrate 101 may be bent when a temperature is changed, and the bend causes a crack of a thin-film. The aforementioned problem may be decreased by using a buffer layer 102 between the substrate 101 and the first conductive type semiconductor layer 110.

In order to improve an optical or electrical characteristic of a light-emitting diode (LED) chip before or after an LED structure growth, the substrate 101 may be completely or partly removed or may be patterned while a chip is manufactured.

For example, the sapphire substrate may be separated in a manner in which a laser is irradiated to an interface between the sapphire substrate and a semiconductor layer, and a silicon substrate or the SiC substrate may be removed by using a polishing method, an etching method, or the like.

When the substrate 101 is removed, another supporting substrate may be used, and the supporting substrate may be bonded to the other side of an original growth substrate by using a reflective metal material or may be formed by inserting a reflection structure into an adhesion layer, so as to improve an optical efficiency of the LED chip.

A patterning operation on a substrate is performed by forming an uneven or slope surface on a main side (e.g., a top surface or both surfaces) or side surfaces of the substrate before or after a growth of an LED structure, and by doing so, a light extraction efficiency is improved. A size of a pattern may be selected in a range from 5 nm to 500 μm, and in order to improve the light extraction efficiency, a regular pattern or an irregular pattern may be selected. In addition, a shape of the pattern may be a column, a cone, a hemisphere, a polygonal shape, or the like.

The sapphire substrate includes crystals having a hexagonal-rhombohedral (Hexa-Rhombo R3c) symmetry in which lattice constants of the crystal in c-axial and a-lateral directions are 13.001 and 4.758, respectively, and the crystal has a C (0001) surface, an A (1120) surface, an R(1102) surface, or the like. In this case, the C (0001) surface easily facilitates the growth of a nitride thin-film, and is stable at a high temperature, so that the C (0001) surface is commonly used as a substrate for the growth of nitride.

The substrate is formed as a Si substrate that is more appropriate for a large diameter and has a relatively low price, so that mass production may be improved. However, since the Si substrate having a (111) surface as a substrate surface has a lattice constant difference of 17% with GaN, a technology is required to suppress occurrence of a defective crystal due to the lattice constant difference. In addition, a thermal expansion difference between silicon and GaN is 56%, so that a technology is required to suppress wafer bend caused due to the thermal expansion difference. Due to the wafer bend, a GaN thin-film may have a crack, and it may be difficult to perform a process control such that dispersion of emission wavelength in a same wafer may be increased.

Since the Si substrate absorbs light that is generated in a GaN-based semiconductor, an external quantum efficiency of a light-emitting device may deteriorate, so that, the Si substrate is removed when required, and a supporting substrate such as Si, Ge, SiAl, ceramic, or metal substrates including a reflective layer may be additionally formed and then may be used.

When the GaN thin-film is grown on a heterogeneous substrate such as the Si substrate, a dislocation density may be increased due to a mismatch between lattice constants of a substrate material and a thin-film material, and the crack and the bend may occur due to the thermal expansion difference. In order to prevent the dislocation and the crack of the emission stack, the buffer layer 102 is disposed between the substrate 101 and the first conductive type semiconductor layer 110. The buffer layer 102 decreases the dispersion of the emission wavelength of the wafer by adjusting a bending level of the substrate while the active layer is grown.

The buffer layer 102 may be formed of AlₓIn_{y}Ga_{(1-x-y)}N (0≦x≦1, 0≦y≦1, 0≦x+y≦1), in particular, GaN, AlN, AlGaN, InGaN, or InGaNAlN, and when required, the buffer layer 102 may be formed of ZrB₂, HfB₂, ZrN, HfN, TiN, or the like. Also, the buffer layer 102 may be formed by combining a plurality of layers or by gradually varying composition of one of the aforementioned materials.

Since the Si substrate and the GaN thin-film has the large thermal expansion difference, when the GaN thin-film is grown on the Si substrate, the GaN thin-film is grown at a high temperature and then is cooled at a room temperature, and at this time, a tensile stress may be applied to the GaN thin-film due to the thermal expansion difference between the Si substrate and the GaN thin-film, such that a crack in the GaN thin-film may easily occur. In order to prevent the crack, a compressive stress may be applied to the GaN thin-film while the GaN thin-film is grown, so that the tensile stress may be compensated.

Due to the lattice constant difference between the Si substrate and the GaN thin-film, the Si substrate may be defective. When the Si substrate is used, a buffer layer having a composite structure is used so as to simultaneously perform a defect control and a stress control to suppress the bend.

For example, AlN is first formed on the substrate 101. In order to prevent reaction between Si and Ga, it is required to use a material that does not contain Ga. Not only AlN but also SiC may be used. AlN is grown by using Al and N sources at a temperature between 400 through 1300° C. so as to have a thickness of 1 nm through 500 nm. When required, a plurality of buffer layers including AlN, GaN, AlₓGa_{y}N, and/or InₓGa_{y}N may be further formed on the AlN buffer layer as an intermediate layer so as to control a stress between the Si substrate and the GaN layer. The intermediate layer may include AlₓGa_{y}N layer in which the composition of Al is gradually decreased.

A V-pit generation layer 140 may be formed on above the residual first conductive type semiconductor layer 130. In some embodiments, the V-pit generation layer 140 may be adjacent to the residual first conductive type semiconductor layer 130. In some embodiments, the V-pit generation layer 140 may have a thickness of 10 nm through 3000 nm. Also, a width D of an opening of a V-pit 141 may be 10 nm through 800 nm.

The V-pit 141 formed in the V-pit generation layer 140 may have a vertical angle θ of 20 through 90 degrees. In other words, when the V-pit 141 is cut into a vertical plane that passes a vertex of the V-pit 141, an angle formed between each of two slopes and the vertical plane may be 20 through 90 degrees.

In an embodiment, the V-pit generation layer 140 may be a GaN layer or an impurity doped GaN layer.

A position where the V-pit 141 is generated in the V-pit generation layer 140 may be adjusted by a growth temperature. That is, if the growth temperature is relatively low, generation of the V-pit 141 may start at a lower position. On the other hand, if the growth temperature is relatively high, the generation of the V-pit 141 may start at a higher position.

If required, the V-pit generation layer 140 may be omitted.

Referring to FIG. 4B, a superlattice layer 150, an active layer 160, and a second conductive type semiconductor layer 170 may be formed on the V-pit generation layer 140.

The first and residual first conductive type semiconductor layers 110 and 130, and the second conductive type semiconductor layer 170 may be formed of semiconductors that are doped with n-type and p-type impurities, respectively, but the first and residual first conductive type semiconductor layers 110 and 130, and the second conductive type semiconductor layer 170 are not limited thereto and thus may be p-type and n-type semiconductor layers, respectively. For example, the first and residual first conductive type semiconductor layers 110 and 130, and the second conductive type semiconductor layer 170 may be formed of, but are not limited to, the group-III nitride semiconductor, e.g., a material having a composition of AlₓIn_{y}Ga_{(1-x-y)}N (0≦x≦1, 0≦y≦1, 0≦x+y≦1). In some embodiments, the first and residual first conductive type semiconductor layers 110 and 130, and the second conductive type semiconductor layer 170 may be formed of a material including an AlGaInP-based semiconductor, an AlGaAs-based semiconductor, or the like. Each of the first and residual first conductive type semiconductor layers 110 and 130 may have a thickness of 10 nm through 5000 nm.

The superlattice layer 150 may have a structure in which a plurality of InₓAl_{y}Ga_{(1-x-y)}N layers (0≦x<1, 0≦y<1, 0≦x+y<1) having different compositions or different impurity levels are repeatedly stacked at least two times or may be a partial insulation material layer. The superlattice layer 150 may decrease propagation of defects toward the active layer 160 and may facilitate diffusion of current so as to improve an internal emission efficiency and to make emission equally occur in a large area.

The active layer 160 may have a multi-quantum well (MQW) structure in which a quantum well layer and a quantum barrier layer, each having a thickness of 1 nm through 20 nm, are alternately stacked. For example, in a case of a nitride semiconductor, the active layer 160 may have a GaN/InGaN, AlGaN/InGaN, AlGaN/GaN, or AlGaN/AlGaN structure. However, in some embodiments, the active layer 160 may have a single-quantum well (SQW) structure.

The second conductive type semiconductor layer 170 may further include an electron block layer that is adjacent to the active layer 160. The electron block layer may have a structure in which a plurality of InₓAl_{y}Ga_{(1-x-y)}N layers having different compositions and a thickness of 3 nm through 50 nm, are stacked or may have at least one layer formed of Al_{y}Ga_{(1-y)}N. Since the electron block layer has a bandgap greater than that of the active layer 160, the electron block layer prevents electrons from entering to the second conductive type semiconductor layer 170 (that is a p-type).

The residual first conductive type semiconductor layer 130, the V-pit generation layer 140, the active layer 160, and the second conductive type semiconductor layer 170 may be formed by using an MOCVD apparatus. In more detail, the residual first conductive type semiconductor layer 130, the V-pit generation layer 140, the active layer 160, and the second conductive type semiconductor layer 170 are formed in a manner in which a reaction gas such as an organic metal compound gas (e.g., trimethylgallium (TMG), trimethylaluminum (TMA), or the like) and a nitrogen containing gas (e g ammonia (NH₃) or the like) are injected into a reaction container in which the substrate 101 is arranged and the substrate 101 is maintained at a high temperature of 700 through 1100° C., while a gallium-based compound semiconductor is grown on the substrate 101, if required, an impurity gas is injected, so that the gallium-based compound semiconductor is stacked as an undoped-type, an n-type, or a p-type. Si is well known as n-type impurity. Zn, Cd, Be, Mg, Ca, Ba, or the like, in particular, Mg and Zn, may be used as p-type impurity.

Referring to FIG. 4C, a portion of each of the V-pit generation layer 140, the superlattice layer 150, the active layer 160, and the second conductive type semiconductor layer 170 may be removed to expose a top surface of the residual first conductive type semiconductor layer 130.

The semiconductor light-emitting device 100 may further include a first electrode 180a and a second electrode 180b for supplying a power. The first electrode 180a and the second electrode 180b may include a material such as Ag, Ni, Al, Rh, Pd, Ir, Ru, Mg, Zn, Pt, Au, ITO, IZO, ZnO, or graphene.

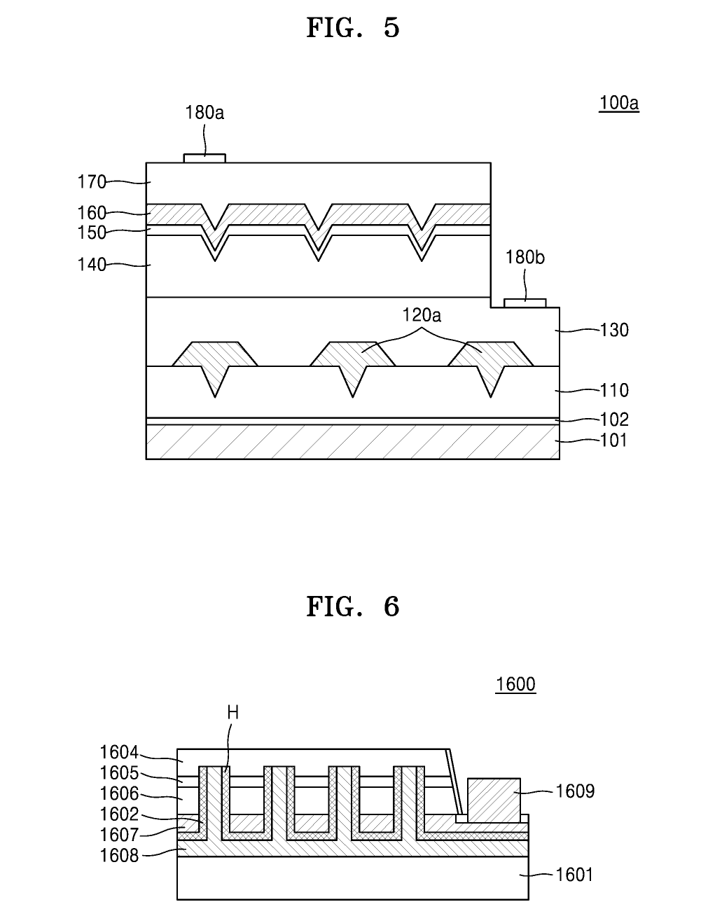

FIG. 5 is a cross-sectional side view that illustrates a semiconductor light-emitting device 100a, according to another exemplary embodiment. Referring to FIG. 5, the present embodiment is different from the embodiment of FIG. 4C in that the semiconductor light-emitting device 100a includes a defect decreasing structure 120a having a mesa shape.

The defect decreasing structure 120a having the mesa shape may be formed in a same phase as the defect decreasing structure 120 having the pyramid shape (refer to FIG. 4C). The difference is that, while a high density silicon source material is supplied to a process of forming the defect decreasing structure 120 having the pyramid shape so as to suppress a lateral growth, the high density silicon source material is not supplied to a process of forming the defect decreasing structure 120a, thus, the defect decreasing structure 120a has the mesa shape as shown in FIG. 5.

In the semiconductor light-emitting devices 100 and 100a shown in FIGS. 4C and 5, the density of the threading dislocations may be significantly decreased due to the defect decreasing structures 120 and 120a, so that a high quality crystal structure of the semiconductor light-emitting devices 100 and 100a may be obtained, and thus an emission quality may be improved.

In order to obtain the semiconductor light-emitting devices 100 and 100a having the high quality crystal structure, according to the related art, the productivity may be low or an external fabrication process may be required such that manufacturing costs and time are increased and a possibility of additional contamination is high. However, according to the manufacturing method according to the one or more exemplary embodiments, the semiconductor light-emitting devices 100 and 100a having the high quality crystal structure may be obtained with low costs and without a possibility of additional contamination.

While each of the semiconductor light-emitting devices 100 and 100a shown in FIGS. 4C and 5 has a structure in which the first electrode 180a, the second electrode 180b, and a light extraction surface face the same side, each of the semiconductor light-emitting devices 100 and 100a may have various structures such as a flip-chip structure in which the first electrode 180a and the second electrode 180b face the opposite side of the light extraction surface, a vertical structure in which the first electrode 180a and the second electrode 180b are formed on opposite surfaces, a vertical and horizontal structure employing an electrode structure in which a plurality of vias are formed in a chip so as to increase an efficiency of current distribution and heat dissipation.

FIG. 6 is a cross-sectional side view of an LED chip 1600 having a light-emitting device, according to an exemplary embodiment.

The LED chip 1600 shown in FIG. 6 may have a structure useful for increasing an efficiency of current distribution and heat dissipation, when a large area light-emitting device chip for a high output for a lighting apparatus is manufactured.

As illustrated in FIG. 6, the LED chip 1600 includes a first conductive type semiconductor layer 1604, an active layer 1605, a second conductive type semiconductor layer 1606, a second electrode layer 1607, an insulating layer 1602, a first electrode layer 1608, and a substrate 1601 that are sequentially stacked. Here, in order to be electrically connected to the first conductive type semiconductor layer 1604, the first electrode layer 1608 includes one or more contact holes H that are electrically insulated from the second conductive type semiconductor layer 1606 and the active layer 1605 and that extend from a surface of the first electrode layer 1608 to a portion of the first conductive type semiconductor layer 1604. In the present embodiment, the first electrode layer 1608 is not an essential element.

The contact hole H extends from an interface of the first electrode layer 1608 to an inner surface of the first conductive type semiconductor layer 1604 via the second conductive type semiconductor layer 1606 and the active layer 1605. The contact hole H extends to an interface between the active layer 1605 and the first conductive type semiconductor layer 1604, and more preferably, the contact hole H extends to the portion of the first conductive type semiconductor layer 1604. Since the contact hole H functions to perform electrical connection and current distribution of the first conductive type semiconductor layer 1604, the contact hole H achieves its purpose when the contact hole H contacts the first conductive type semiconductor layer 1604, thus, it is not required for the contact hole to extend to an outer surface of the first conductive type semiconductor layer 1604.

The second electrode layer 1607 that is formed on the second conductive type semiconductor layer 1606 may be formed of a material selected from the group consisting of Ag, Ni, Al, Rh, Pd, Ir, Ru, Mg, Zn, Pt, and Au, in consideration of a light reflection function and an ohmic contact with the second conductive type semiconductor layer 1606, and may be formed via a sputtering process or a deposition process.

The contact hole H has a shape that penetrates through the second electrode layer 1607, the second conductive type semiconductor layer 1606, and the active layer 1605 so as to be connected with the first conductive type semiconductor layer 1604. The contact hole H may be formed via an etching process using ICP-RIE or the like.

The insulating layer 1602 is formed to cover side walls of the contact hole H and a top surface of the second conductive type semiconductor layer 1606. In this case, a portion of the first conductive type semiconductor layer 1604 that corresponds to a bottom surface of the contact hole H may be exposed. The insulating layer 1602 may be formed by depositing an insulation material such as SiO₂, SiOₓN_{y}, SiₓN_{y}, or the like. The insulating layer 1602 may be deposited with a thickness range from 0.01 μm to 3 μm at a temperature of 500° C. or less via a CVD process.

The second electrode layer 1607 that includes a conductive via formed by filling a conductive material is formed in the contact hole H. A plurality of the vias may be formed in a light-emitting device region. The number of vias and a contact area of the vias may be adjusted so that an area of the vias that contact the first conductive type semiconductor layer 1604 is within a range between 0.5% and 20% of an area of the light-emitting device region. A planar radius of the area of the vias that contact the first conductive type semiconductor layer 1604 is within a range between 1 μm and 50 μm, and the number of vias may be between 1 and 48,000 for each light-emitting device region, according to an area of each light-emitting device region. Although the number of vias may vary according to the area of each light-emitting device region, the number of vias may be at least 3. A distance between the vias may correspond to a matrix array of rows and columns in the range between 5 μm and 500 μm, and more preferably, in the range between 50 μm and 450 μm. When the distance between the vias is less than 5 μm, the number of vias is increased so that an emission area is relatively decreased such that an emission efficiency deteriorates. When the distance is greater than 500 μm, a current spread may be difficult such that an emission efficiency may deteriorate. A depth of the contact hole H may vary according to a thickness of the second conductive type semiconductor layer 1606 and a thickness of the active layer 1605 and may be in the range between 0.5 μm and 10.0 μm.

Afterward, the substrate 1601 is formed on a surface of the first electrode layer 1608. In this structure, the substrate 1601 may be electrically connected to the first conductive type semiconductor layer 1604 via the conductive via that contacts the first conductive type semiconductor layer 1604.

The substrate 1601 may be formed of a material selected from the group consisting of Au, Ni, Al, Cu, W, Si, Se, GaAs, SiAl, Ge, SiC, AlN, Al₂O₃, GaN, and AlGaN, via a plating process, a sputtering process, a deposition process, or an adhesion process. However, a material and a forming method with respect to the substrate 1601 are not limited thereto.

In order to decrease a contact resistance of the contact hole H, a total number of contact holes H, a shape of the contact hole H, a pitch of the contact hole H, a contact area of the contact hole H with respect to the first and second conductive type semiconductor layers 1604 and 1606, or the like may be appropriately adjusted, and since the contact holes H are arrayed in various forms along rows and columns, a current flow may be improved.

The first conductive type semiconductor layer 1604 may include a defect decreasing structure as described above with reference to FIGS. 2A through 3B.

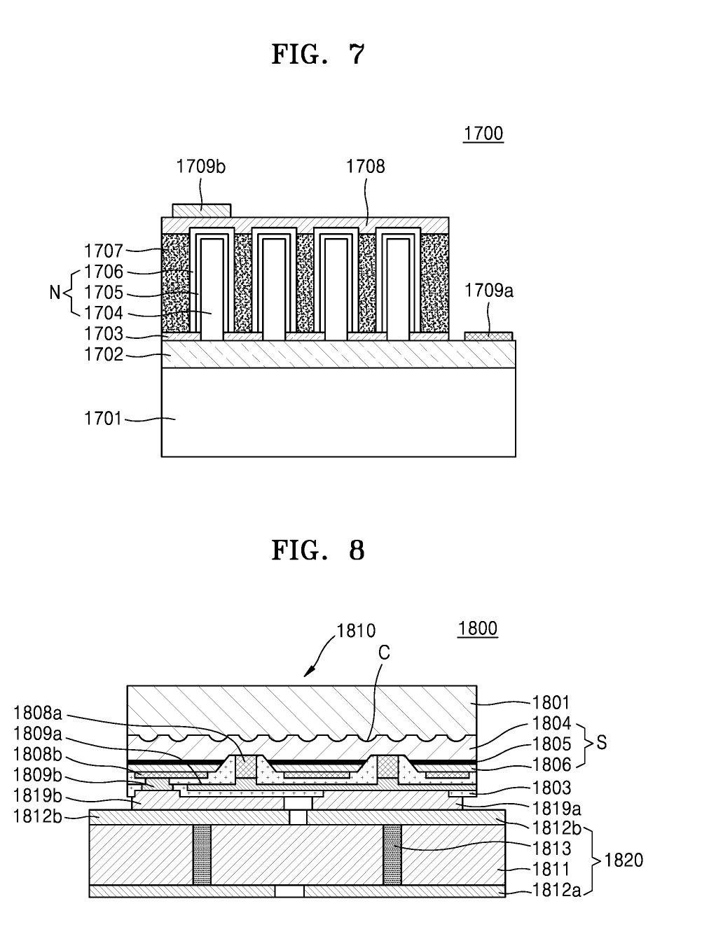

FIG. 7 is a cross-sectional side view of a light-emitting device 1700, according to another exemplary embodiment.

Since an LED lighting apparatus provides an improved heat dissipation characteristic, it is preferable to apply an LED chip having a small calorific value to the LED lighting apparatus, in consideration of a total heat dissipation performance. An example of the LED chip may be an LED chip having a nano structure (hereinafter, referred to as a “nano LED chip”).

An example of the nano LED chip includes a core-shell type nano LED chip. The core-shell type nano LED chip generates a relatively small amount of heat due to its small combined density, and increases its emission area by using the nano structure so as to increase emission efficiency. Also, the core-shell type nano LED chip may obtain a non-polar active layer, thereby preventing efficiency deterioration due to polarization, so that a droop characteristic may be improved.

As illustrated in FIG. 7, the nano LED chip 1700 includes a plurality of nano emission structures N that are formed on a substrate 1701. In the present embodiment, the nano emission structure N has a rod structure as a core-shell structure, but in another embodiment, the nano emission structure N may have a different structure such as a pyramid structure.

The nano LED chip 1700 includes a base layer 1702 formed on the substrate 1701. The base layer 1702 may be a layer to provide a growth surface for the nano emission structures N and may be formed of a first conductive semiconductor. A mask layer 1703 having open areas for a growth of the nano emission structures N (in particular, a core) may be formed on the base layer 1702. The mask layer 1703 may be formed of a dielectric material such as SiO₂ or SiNx.

In the nano emission structure N, a first conductive nano core 1704 is formed by selectively growing the first conductive semiconductor by using the mask layer 1703 having open areas, and an active layer 1705 and a second conductive type semiconductor layer 1706 are formed as a shell layer on a surface of the first conductive nano core 1704. By doing so, the nano emission structure N may have a core-shell structure in which the first conductive semiconductor is a nano core, and the active layer 1705 and the second conductive type semiconductor layer 1706 that surround the nano core are the shell layer.

In the present embodiment, the nano LED chip 1700 includes a filling material 1707 that fills gaps between the nano emission structures N. The filling material 1707 may structurally stabilize the nano emission structures N. The filling material 1707 may include, but is not limited to, a transparent material such as SiO₂. An ohmic contact layer 1708 may be formed on the nano emission structure N so as to contact the second conductive type semiconductor layer 1706. The nano LED chip 1700 includes first and second electrodes 1709a and 1709b that contact the base layer 1702, which is formed of the first conductive semiconductor, and the ohmic contact layer 1708, respectively.

By varying a diameter, a component, or a doping density of the nano emission structure N, light having at least two different wavelengths may be emitted from one device. By appropriately adjusting the light having the different wavelengths, white light may be realized in the one device without using a phosphor. In addition, by combining the one device with another LED chip or combining the one device with a wavelength conversion material such as a phosphor, light having desired various colors or white light having different color temperatures may be realized.

The first conductive nano core 1704 may include a defect decreasing structure as described above with reference to FIGS. 2A through 3B.

FIG. 8 is a cross-sectional side view of a light-emitting device 1800, according to another exemplary embodiment.

FIG. 8 illustrates a semiconductor light-emitting device 1800 that is a light source to be applied to a light source package and includes an LED chip 1810 mounted on a mounting substrate 1820.

The semiconductor light-emitting device 1800 shown in FIG. 8 includes the mounting substrate 1820 and the LED chip 1810 that is mounted on the mounting substrate 1820. The LED chip 1810 is different from the LED chips in the aforementioned embodiments.

The LED chip 1810 includes an emission stack S that is disposed on a surface of the substrate 1801, and first and second electrodes 1808a and 1808b that are disposed on the other surface of the substrate 1801 with respect to the emission stack S. Also, the LED chip 1810 includes an insulation unit 1803 to cover the first and second electrodes 1808a and 1808b.

The first and second electrodes 1808a and 1808b may be connected to first and second electrode pads 1819a and 1819b via first and second electric power connection units 1809a and 1809b.

The emission stack S may include a first conductive type semiconductor layer 1804, an active layer 1805, and a second conductive type semiconductor layer 1806 that are sequentially disposed on the substrate 1801. The first electrode 1808a may be provided as a conductive via that contacts the first conductive type semiconductor layer 1804 by penetrating through the second conductive type semiconductor layer 1806 and the active layer 1805. The second electrode 1808b may contact the second conductive type semiconductor layer 1806.

A plurality of the vias may be formed in a light-emitting device region. The number of vias and a contact area of the vias may be adjusted so that an area of the vias that contact a first conductive-type semiconductor is within a range between 1% and 5% of an area of the light-emitting device region. A planar radius of the area of the vias that contact the first conductive-type semiconductor is within a range between 5 μm and 50 μm, and the number of vias may be between 1 and 50 vias for each light-emitting device region, according to an area of each light-emitting device region. Although the number of vias may vary according to the area of each light-emitting device region, the number of vias may be at least 3. A distance between the vias may correspond to a matrix array of rows and columns in the range between 100 μm and 500 μm, and more preferably, in the range between 150 μm and 450 μm. When the distance between the vias is less than 100 μm, the number of vias is increased so that an emission area is relatively decreased such that an emission efficiency deteriorates. However, when the distance is greater than 500 μm, a current spread may be difficult such that an emission efficiency may deteriorate. A depth of the vias may vary according to a second semiconductor layer and an active layer and may be in the range between 0.5 μm and 5.0 μm.

A conductive ohmic material is deposited on the emission stack S so that the first and second electrodes 1808a and 1808b are formed. The first electrode 1808a and the second electrode 1808b may be an electrode including at least one material selected from the group consisting of Ag, Al, Ni, Cr, Cu, Au, Pd, Pt, Sn, Ti, W, Rh, Ir, Ru, Mg, Zn, and an alloy thereof. For example, the second electrode 1808b may be formed as an ohmic electrode including an Ag layer deposited with respect to the second conductive type semiconductor layer 1806. The Ag-ohmic electrode functions to reflect light. Selectively, a single layer including Ni, Ti, Pt, or W or a layer of an alloy thereof may be alternately stacked on the Ag layer. More preferably, a Ni/Ti layer, a TiW/Pt layer, or a Ti/W layer may be stacked below the Ag layer or the aforementioned layers may be alternately stacked below the Ag layer.

The first electrode 1808a may be formed in a manner that a Cr layer may be stacked with respect to the first conductive type semiconductor layer 1804 and then Au/Pt/Ti layers may be sequentially stacked on the Cr layer, or an Al layer may be stacked with respect to the second conductive type semiconductor layer 1806 and then Ti/Ni/Au layers may be sequentially stacked on the Al layer.

In order to improve an ohmic characteristic or a reflective characteristic, the first and second electrodes 1808a and 1808b may be formed of various materials or may have various stacking structures, other than the aforementioned materials and structures.

The insulation unit 1803 may have an open area to expose a portion of the first and second electrodes 1808a and 1808b, and the first and second electrode pads 1819a and 1819b may contact the first and second electrodes 1808a and 1808b. The insulation unit 1803 may be formed by depositing SiO₂ and/or SiN via a CVD process at a temperature 500° C. or less and may have a thickness between 0.01 μm and 3 μm.

The first and second electrodes 1808a and 1808b may be disposed in the same direction, and as will be described later, the first and second electrodes 1808a and 1808b may be mounted in the form of a flip-chip in a lead frame. In this case, the first and second electrodes 1808a and 1808b may be disposed to face in the same direction.

In particular, the first electric power connection unit 1809a may be formed by the first electrode 1808a having a conductive via that penetrates through the active layer 1805 and the second conductive type semiconductor layer 1806 and then is connected to the first conductive type semiconductor layer 1804 in the emission stack S.

In order to decrease a contact resistance between the conductive via and the first electric power connection unit 1809a, a total number, shapes, pitches, a contact area with the first conductive type semiconductor layer 1804, or the like of the conductive via and the first electric power connection unit 1809a may be appropriately adjusted, and since the conductive via and the first electric power connection unit 1809a are arrayed in rows and columns, a current flow may be improved.

An electrode structure of the other side of the semiconductor light-emitting device 1800 may include the second electrode 1808b that is directly formed on the second conductive type semiconductor layer 1806, and the second electric power connection unit 1809b that is formed on the second electrode 1808b. The second electrode 1808b may function to form an electrical ohmic connection with the second electric power connection unit 1809b and may be formed of a light reflection material, so that, when the LED chip 1810 is mounted as a flip-chip structure, the second electrode 1808b may efficiently discharge light, which is emitted from the active layer 1805, toward the substrate 1801. Obviously, according to a major light emission direction, the second electrode 1808b may be formed of a light-transmitting conductive material such as transparent conductive oxide.

The aforementioned two electrode structures may be electrically separated from each other by using the insulation unit 1803. Any material or any object having an electrical insulation property may be used as the insulation unit 1803, but it is preferable to use a material having a low light-absorption property. For example, silicon oxide or silicon nitride such as SiO₂, SiOₓN_{y}, SiₓN_{y}, or the like may be used. When required, the insulation unit 1803 may have a light reflection structure in which a light reflective filler is distributed throughout a light transmitting material.

The first and second electrode pads 1819a and 1819b may be connected to the first and second electric power connection units 1809a and 1809b, respectively, and thus may function as external terminals of the LED chip 1810. For example, the first electrode pad 1819a and the second electrode pad 1819b may be formed of Au, Ag, Al, Ti, W, Cu, Sn, Ni, Pt, Cr, NiSn, TiW, AuSn, or a eutectic alloy thereof. In this case, when the first and second electrode pads 1819a and 1819b are mounted on the mounting substrate 1820, the first and second electrode pads 1819a and 1819b may be bonded to the mounting substrate 1820 by using eutectic metal, so that a separate solder bump that is generally used in flip-chip bonding may not be used. Compared to a case of using the solder bump, the mounting method using the eutectic metal may achieve a more excellent heat dissipation effect. In this case, in order to obtain the excellent heat dissipation effect, the first and second electrode pads 1819a and 1819b may be formed while having large areas.

The substrate 1801 and the emission stack S may be understood by referring to the aforementioned descriptions, unless contrary description is provided. Also, although not particularly illustrated, a buffer layer may be formed between the emission stack S and the substrate 1801, and in this regard, the buffer layer may be formed as an undoped semiconductor layer including nitride or the like, so that the buffer layer may decrease a lattice defect of an emission structure that is grown on the buffer layer.

The substrate 1801 may have first and second primary surfaces that face each other, and in this regard, a convex-concave structure may be formed on at least one of the first and second primary surfaces. The convex-concave structure that is arranged on one surface of the substrate 1801 may be formed of the same material as the substrate 1801 since a portion of the substrate 1801 is etched, or may be formed of a different material from the substrate 1801.

As in the present embodiment, since the convex-concave structure is formed at an interface between the substrate 1801 and the first conductive type semiconductor layer 1804, a path of light emitted from the active layer 1805 may vary, such that a rate of light that is absorbed in the semiconductor layer may be decreased and a light-scattering rate may be increased; thus, the light extraction efficiency may be increased.

In more detail, the convex-concave structure may have a regular shape or an irregular shape. Heterogeneous materials that form the convex-concave structure may include a transparent conductor, a transparent insulator, or a material having excellent reflectivity. In this regard, the transparent insulator may include, but is not limited to, SiO₂, SiNx, Al₂O₃, HfO, TiO₂, or ZrO, the transparent conductor may include, but is not limited to, TCO such as indium oxide containing ZnO or an additive including Mg, Ag, Zn, Sc, Hf, Zr, Te, Se, Ta, W, Nb, Cu, Si, Ni, Co, Mo, Cr, or Sn, and the reflective material may include, but is not limited to, Ag, Al, or DBR that is formed of a plurality of layers having different refractive indexes.

The substrate 1801 may be removed from the first conductive type semiconductor layer 1804. In order to remove the substrate 1801, a laser lift off (LLO) process using a laser, an etching process, or a grinding process may be performed. After the substrate 1801 is removed, the convex-concave structure may be formed on a top surface of the first conductive type semiconductor layer 1804.

As illustrated in FIG. 8, the LED chip 1810 is mounted on the mounting substrate 1820. The mounting substrate 1820 has a structure in which upper and lower electrode layers 1812b and 1812a are formed on a top surface and a bottom surface of a substrate body 1811, respectively, and a via 1813 penetrates through the substrate body 1811 so as to connect the upper and lower electrode layers 1812b and 1812a. The substrate body 1811 may be formed of resin, ceramic, or metal, and the upper and lower electrode layers 1812b and 1812a may be metal layers including Au, Cu, Ag, Al, or the like.

An example of a substrate on which the LED chip 1810 is mounted is not limited to the mounting substrate 1820 of FIG. 8, and thus any substrate having a wiring structure to drive the LED chip 1810 may be used. For example, it is possible to provide a package structure in which the LED chip 1810 is mounted in a package body having a pair of lead frames.

The first conductive type semiconductor layer 1804 may include a defect decreasing structure as described above with reference to FIGS. 2A through 3B.

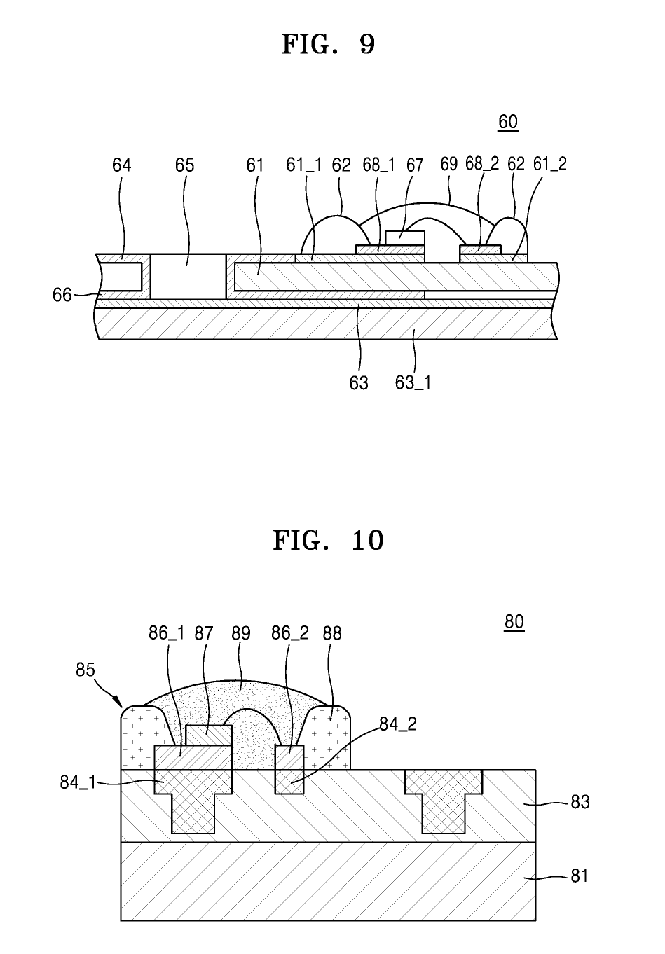

FIG. 9 is a cross-sectional side view that illustrates a light-emitting package 60 including a semiconductor light-emitting device, according to an exemplary embodiment.

Referring to FIG. 9, a substrate 61 is an insulation substrate and has a structure in which circuit patterns 61_1 and 61_2 formed of a copper laminate are formed on a top surface of the insulation substrate, and an insulation thin film layer 63 that is thinly coated as an insulation material may be formed on a bottom surface of the insulation substrate. Here, various coating methods such as a sputtering method or a spraying method may be used. Also, top and bottom heat diffusion plates 64 and 66 may be formed on the top and bottom surfaces of the substrate 61 so as to dissipate heat that is generated in the light-emitting package 60, and in particular, the top heat diffusion plate 64 directly contacts the circuit pattern 61_1. For example, the insulation material that is used as the insulation thin film layer 63 has thermal conductivity that is significantly lower than that of a heat pad, but since the insulation thin film layer 63 has a very small thickness, the insulation thin film layer 63 may have a thermal resistance that is significantly lower than that of the heat pad. The heat that is generated in the light-emitting package 60 may be transferred to the bottom heat diffusion plate 66 via the top heat diffusion plate 64 and then may be dissipated to a sash 63_1.

Two through holes 65 may be formed in the substrate 61 and the top and bottom heat diffusion plates 64 and 66 so as to be vertical to the substrate 61. An LED package may include an LED chip 67 including one of the semiconductor light-emitting devices 100 and 100a, LED electrodes 68_1 and 68_2, a plastic molding case 62, a lens 69, or the like. The substrate 61 may have a circuit pattern that is formed by laminating a copper layer onto an FR4-core that is a ceramic or epoxy resin-based material and then by performing an etching process.

The light-emitting package 60 may have a structure in which at least one of a red LED that emits red light, a green LED that emits green light, and a blue LED that emits blue light is mounted. At least one phosphor material may be coated on a top surface of the blue LED.

The phosphor material may be sprayed while including a particle powder that is mixed with a resin. The phosphor powder may be fired and thus may be formed in the form of a ceramic plate layer on the top surface of the LED. A size of the phosphor powder may be from 1 μm to 50 μm or, for example, from 5 μm to 30 μm. In a case of a nano phosphor, it may be a quantum dot having a size of from 1 nm to 500 nm or, for example, from 5 nm to 200 nm.

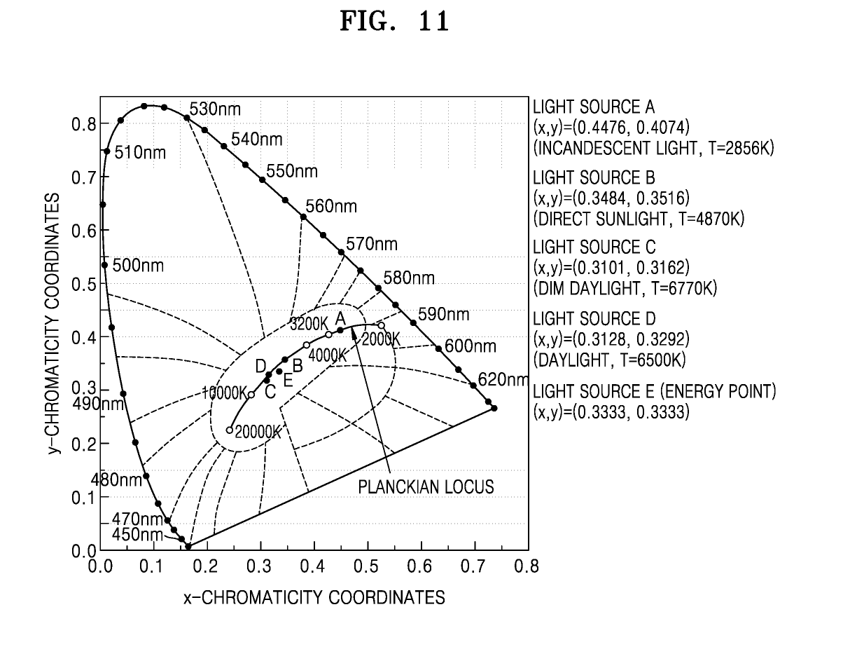

FIG. 10 is a cross-sectional side view of a light-emitting package 80, according to another exemplary embodiment.

Referring to FIG. 10, a circuit board 80 includes an insulation resin 83 that is coated on a metal substrate 81, circuit patterns 84_1 and 84_2 that are formed in the insulation resin 83, and an LED chip that is mounted to be electrically connected with the circuit patterns 84_1 and 84_2. Here, the insulation resin 83 having a thickness that is equal to or less than 200 μm may be laminated as a solid-state film on a metal substrate, or may be coated in a liquid state on the metal substrate by using spin coating or a molding method using a blade. A size of an insulation resin layer having an insulation circuit pattern may be equal to or less than a size of the metal substrate. Also, the circuit patterns 84_1 and 84_2 are formed in a manner in which a metal material such as copper is filled in shapes of the circuit patterns 84_1 and 84_2 that are engraved in the insulation resin 83.

Referring to FIG. 10, an LED module 85 includes an LED chip 87, LED electrodes 86_1 and 86_2, a plastic molding case 88, and a lens 89.

The LED chip 87 may include the semiconductor light-emitting device 100 or 100a, and may emit blue light, green light, or red light, according to a type of a compound semiconductor consisting of the LED chip 87. Alternatively, the LED chip 87 may emit ultraviolet (UV) rays. In some embodiments, the semiconductor light-emitting device 100 or 100a may be formed of an UV light diode chip, a laser diode chip, or an organic light-emitting device (OLED) chip. However, according to one or more exemplary embodiments, the semiconductor light-emitting device 100 or 100a may be formed of various light devices other than the aforementioned elements.

The semiconductor light-emitting device 100 or 100a may be configured so that a Color Rendering Index (CRI) can be adjusted from a CRI of 40 to a CRI of 100 and also may generate a variety of white light in the color temperature range between from 2,000K to 20,000K, and when required, the light-emitting device 100, 200, or 300 may adjust a lighting color according to the ambient atmosphere or mood by generating visible light having a purple, blue, green, red, or orange color, or infrared light. Also, the semiconductor light-emitting device 100 or 100a may generate light having a special wavelength capable of promoting growth of plants.

White light that corresponds to a combination of light emitted by the blue LED and/or an UV LED and light emitted by the yellow, green, and red phosphors and/or green and red light-emitting devices may have at least two peak wavelengths and may be positioned in a region defined by (x, y) coordinates (0.4476, 0.4074), (0.3484, 0.3516), (0.3101, 0.3162), (0.3128, 0.3292), and (0.3333, 0.3333) of a CIE 1931 coordinate system. Alternatively, the white light may be positioned in a region that is surrounded by the line segment and a black body radiation spectrum. A color temperature of the white light may be between 2,000K and 20,000K. FIG. 11 illustrates a color temperature (i.e., a Planckian spectrum).

For example, phosphors that are used in an LED may have general formulas and colors as below.

oxide-based phosphors: yellow and green Y₃Al₅O₁₂:Ce, Tb₃Al₅O₁₂:Ce, Lu₃Al₅O₁₂:Ce

silicate-based phosphors: yellow and green (Ba, Sr)₂SiO₄:Eu, yellow and orange (Ba,Sr)₃SiO₅:Ce

nitride-based phosphors: green β-SiAlON:Eu, yellow La₃Si₆N₁₁:Ce, orange α-SiAlON:Eu, red CaAlSiN₃:Eu, Sr₂Si₅N₈:Eu, SrSiAl₄N₇:Eu, SrLiAl₃N₄:Eu,

Ln₄₋ₓ(Eu_{z}M_{1-z})ₓSi_{12-y}Al_{y}O_{3+x+y}N_{18-x-y}(0.5≦x≦3,0<z<0.3,0<y≦4) Formula(1)

Here, in Formula (1), Ln may be at least one element type selected from the group consisting of group-IIIa elements and rare earth elements, and M may be at least one element type selected from the group consisting of Ca, Ba, Sr, and Mg.

fluoride-based phosphors: KSF-based red K₂SiF₆:Mn₄⁺, K₂TiF₆:Mn₄⁺, NaYF₄:Mn₄⁺, NaGdF₄:Mn₄⁺

In general, the general formulas of the phosphors must match with the stoichiometry, and each element may be substituted for another element in the same group of the periodic table. For example, Sr may be substituted for Ba, Ca, Mg, or the like of the alkaline-earth metal elements group II, and Y may be substituted for Tb, Lu, Sc, Gd, or the like of lanthanide-base elements. Also, Eu that is an activator may be substituted for Ce, Tb, Pr, Er, Yb, or the like according to a desired energy level, and the activator may be solely used or a sub-activator may be additionally used for a characteristic change.

As a substitute for the phosphors, materials such as a quantum dot or the like may be used, and in this case, the LED, the phosphors, and the quantum dot may be combined or the LED and the quantum dot may be used.

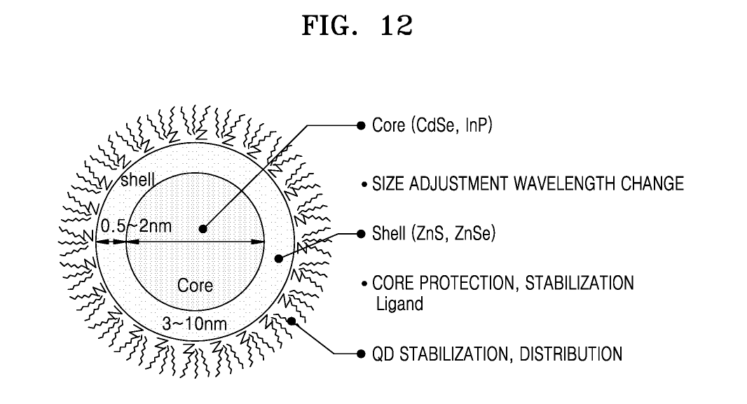

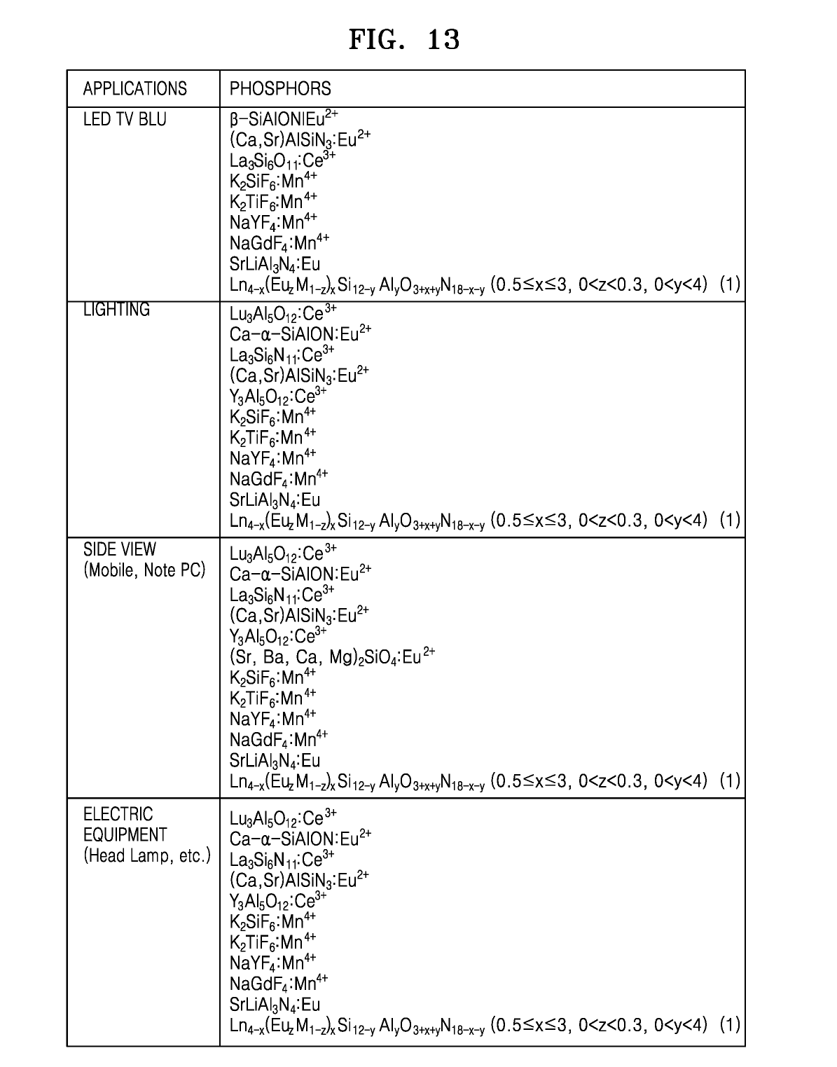

FIG. 12 illustrates an example of the structure of the quantum dot that may be used in the light-emitting device of the present application. The quantum dot may have a structure of a core (from 3 nm to 10 nm) such as CdSe, InP, or the like, a shell (from 0.5 nm to 2 nm) such as ZnS, ZnSe, or the like, and a ligand for stabilization of the core-shell, and may realize various colors according to sizes.

FIG. 13 illustrates phosphor types according to application fields of a white light-emitting apparatus using a blue-light LED.

Phosphors or quantum dots may be sprayed on an LED chip or a light-emitting device, may be used as a covering in the form of a thin-film, or may be attached in the form of a film-sheet or a ceramic phosphor sheet.

The phosphors or the quantum dots may be sprayed by using a dispensing method, a spray coating method, or the like, and in this regard, the dispensing method includes a pneumatic method and a mechanical method such as a screw, a linear type, or the like. A jetting method may allow a dotting amount control via a minute-amount discharge operation, and a color-coordinates control via the dotting amount control. A method of collectively spraying phosphors on a wafer level or a substrate of the light-emitting device may facilitate a control of productivity and a thickness of the light-emitting device.

The method of covering the phosphors or the quantum dots in the form of a thin-film on the light-emitting device or the LED chip may be performed by using an electrophoretic deposition method, a screen printing method, or a phosphor molding method, and one of the aforementioned methods may be used according to whether it is required to cover side surfaces of the LED chip.

In order to control an efficiency of a long-wavelength light-emitting phosphor that re-absorbs light that is emitted at a short-wavelength and that is from among at least two types of phosphors having different emission wavelengths, the at least two types of phosphors having different emission wavelengths may be distinguished, and in order to minimize wavelength re-absorption and interference of the LED chip and the at least two types of phosphors, a DBR (ODR) layer may be arranged between layers.

In order to form a uniform coating layer, the phosphors may be arranged in the form of a film or a ceramic sheet and then may be attached on the LED chip or the light-emitting device.

In order to vary a light efficiency and a light distribution characteristic, a light conversion material may be positioned in a remote manner, and here, the light conversion material may be positioned together with a light-transmitting polymer material, a glass material, or the like according to durability and heat resistance of the light conversion material.

Since the phosphor spraying technology performs a major role in the determination of a luminescent quality of an LED device, various techniques to control a thickness of a phosphor-coated layer, uniform distribution of the phosphors, or the like are being studied. Also, the quantum dot may be positioned at the LED chip or the light-emitting device in the same manner as the phosphors, and in this regard, the quantum dot may be positioned between glass materials or between light-transmitting polymer materials, thereby performing light conversion.

In order to protect the LED chip or the light-emitting device against an external environment or to improve an extraction efficiency of light that is externally emitted from the light-emitting device, a light-transmitting material as a filling material may be arranged on the LED chip or the light-emitting device.

Here, the light-transmitting material may be a transparent organic solvent including epoxy, silicone, a hybrid of epoxy and silicone, or the like, and may be used after being hardened via heating, light irradiation, a time-elapse, or the like.

With respect to silicone, polydimethyl siloxane is classified into a methyl-base, and polymethylphenyl siloxane is classified into a phenyl-base, and depending on the methyl-base and the phenyl-base, silicone differs in refractive index, water-permeation rate, light transmittance, light fastness, and heat-resistance. Also, silicone differs in hardening time according to a cross linker and a catalyst, thereby affecting distribution of the phosphors.

The light extraction efficiency varies according to a refractive index of the filling material, and in order to minimize a difference between a refractive index of an outermost medium of emitted blue light of the LED chip and a refractive index of the blue light that is emitted to the outside air, at least two types of silicon having different refractive indexes may be sequentially stacked.

In general, the methyl-base has the most excellent heat-resistance, and variation due to a temperature increase is decreased in order of the phenyl-base, the hybrid, and epoxy. Silicone may be divided into a gel type, an elastomer type, and a resin type according to a hardness level.

The light-emitting device may further include a lens to radially guide light that is irradiated from a light source, and in this regard, a pre-made lens may be attached on the LED chip or the light-emitting device, or a liquid organic solvent may be injected into a molding frame in which the LED chip or the light-emitting device is mounted and then may be hardened.

The lens may be directly attached on the filling material on the LED chip or may be separated from the filling material by bonding only an outer side of the light-emitting device and an outer side of the lens. The liquid organic solvent may be injected into the molding frame via injection molding, transfer molding, compression molding, or the like.

According to a shape (e.g., a concave shape, a convex shape, a concave-convex shape, a conical shape, a geometrical shape, or the like) of the lens, the light distribution characteristic of the light-emitting device may vary, and the shape of the lens may be changed according to requirements for the light efficiency and the light distribution characteristic.

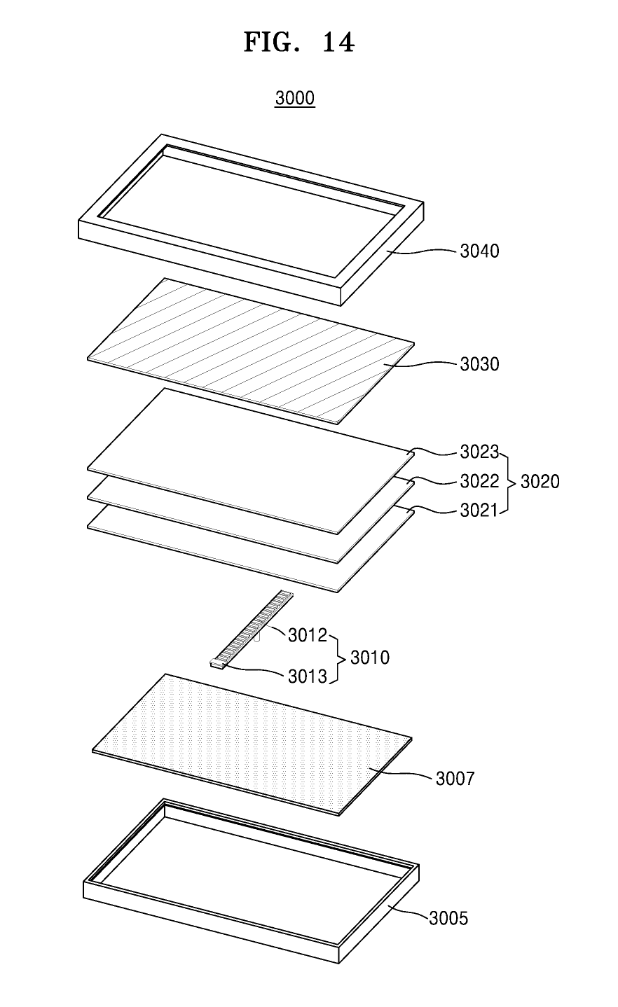

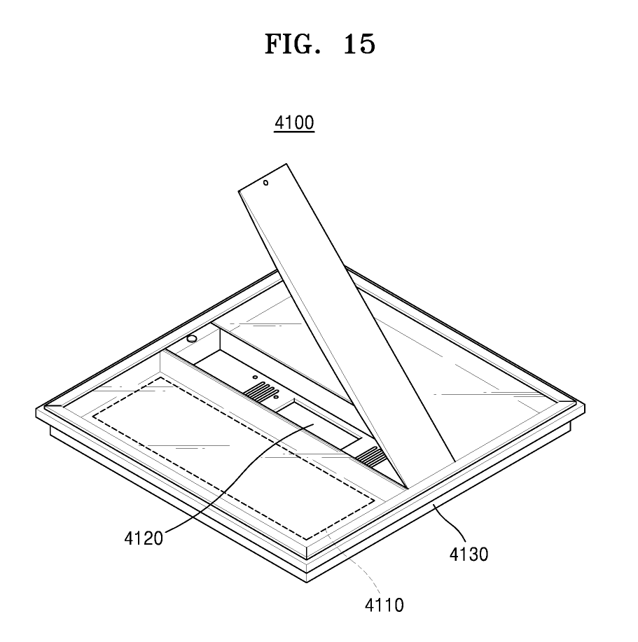

FIG. 14 is an exploded perspective view that illustrates a direct-type backlight assembly 3000 including a light-emitting device array of LED chips, which is manufactured by using the method of manufacturing a semiconductor light-emitting device, according to an exemplary embodiment.

As illustrated in FIG. 14, the direct-type backlight assembly 3000 may include a bottom cover 3005, a reflective sheet 3007, an emission module 3010, an optical sheet 3020, a liquid crystal panel 3030, and a top cover 3040. In the present embodiment, the light-emitting device array may be used as the emission module 3010 included in the direct-type backlight assembly 3000.

In the present embodiment, the emission module 3010 may include a light-emitting device array 3012 including at least one light-emitting device package and a circuit board, and a controller 3013. As in the aforementioned exemplary embodiments, the light-emitting device array 3012 may include the semiconductor light-emitting device 100 described with reference to FIG. 4C or the like, or a light-emitting apparatus. Also, the light-emitting device array 3012 may receive a power for emission from a light-emitting device driving part outside the direct-type backlight assembly 3000, and the light-emitting device driving part may adjust a current that is applied to the light-emitting device array 3012.

The optical sheet 3020 may be arranged on the emission module 3010 and may include a diffusion sheet 3021, a light-collecting sheet 3022, and a protective sheet 3023. That is, the diffusion sheet 3021 that diffuses light emitted from the emission module 3010, the light-collecting sheet 3022 that collects light diffused by the diffusion sheet 3021 so as to increase brightness, and the protective sheet 3023 that protects the light-collecting sheet 3022 and assures a viewing angle may be sequentially arranged on the emission module 3010.

The top cover 3040 may frame a boundary of the optical sheet 3020 and may be coupled with the bottom cover 3005.

The liquid crystal panel 3030 may be further arranged between the optical sheet 3020 and the top cover 3040. The liquid crystal panel 3030 may include a first substrate and a second substrate that are bonded to each other by having a liquid crystal layer interposed therebetween. A plurality of gate lines and a plurality of data lines cross each other to define pixel areas on the first substrate, and a plurality of thin-film transistors (TFTs) are arranged at all cross points of the pixel areas and are connected to pixel electrodes, respectively, that are mounted in the pixel areas. A color filter of R, G, B colors and a black matrix that covers boundaries of the R, G, B colors, the gate line, the data line, and the TFT that correspond to the pixel areas, respectively, may be arranged at the second substrate.

FIG. 15 illustrates a flat panel semiconductor light-emitting apparatus 4100 including a light-emitting device array of LED chips and a light-emitting device module, which are manufactured by using the method of manufacturing a semiconductor light-emitting device, according to an exemplary embodiment.

The flat panel semiconductor light-emitting apparatus 4100 may include a light source 4110, a power supplier 4120, and a housing 4130. In one or more exemplary embodiments, the light source 4110 may include the light-emitting device array including a light-emitting apparatus or a semiconductor chip.

The light source 4110 may include the light-emitting device array, and as illustrated in FIG. 15, the light source 4110 may be entirely flat.

The power supplier 4120 may be configured to supply a power to the light source 4110.

The housing 4130 may have a housing space to internally house the light source 4110 and the power supplier 4120 therein, and may have a hexahedral shape having one open side surface but a shape of the housing 4130 is not limited thereto. The light source 4110 may emit light to the open side surface of the housing 4130.

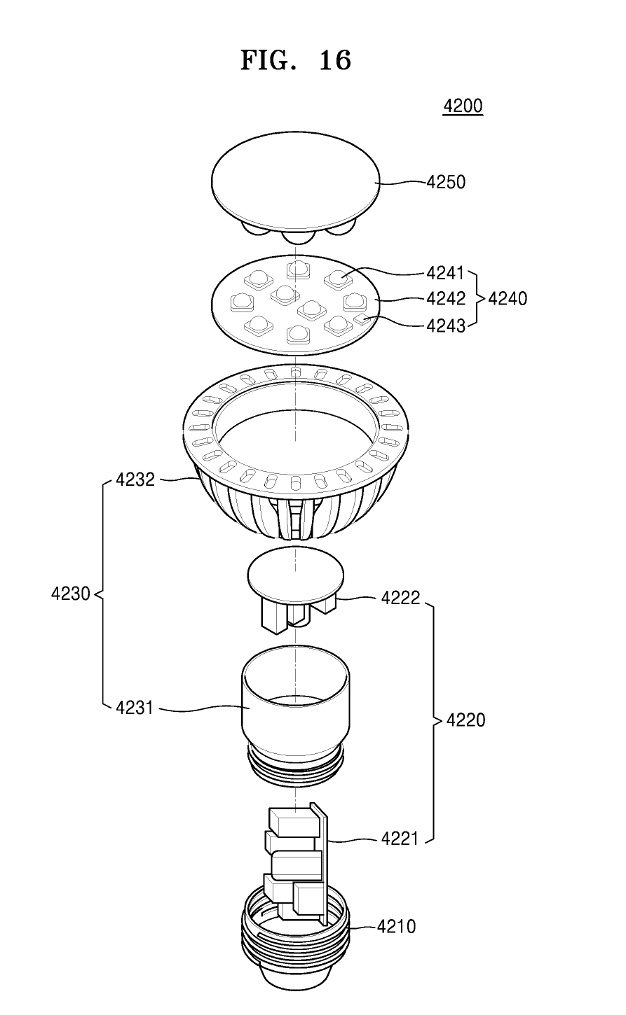

FIG. 16 illustrates a bulb type lamp as a semiconductor light-emitting apparatus 4200 including a light-emitting device array of LED chips and a light-emitting device module, which are manufactured by using the method of manufacturing a semiconductor light-emitting device, according to an exemplary embodiment. The semiconductor light-emitting apparatus 4200 may include a socket 4210, a power part 4220, a heat dissipation part 4230, a light source 4240, and an optical part 4250. In the present embodiment, the light source 4240 may include the light-emitting device array including a light-emitting apparatus or a semiconductor chip.

The socket 4210 may be configured to be used in an existing lighting apparatus. A power supplied to the semiconductor light-emitting apparatus 4200 may be applied via the socket 4210. As illustrated in FIG. 16, the power part 4220 may be divided into a first power part 4221 and a second power part 4222 and then may be assembled.

The heat dissipation part 4230 may include an inner heat dissipation part 4231 and an outer heat dissipation part 4232. The inner heat dissipation part 4231 may be directly connected to the light source 4240 and/or the power part 4220 so as to allow heat to be transferred to the outer heat dissipation part 4232. The optical part 4250 may include an inner optical part and an outer optical part and may function to uniformly distribute light that is emitted from the light source 4240.

The light source 4240 may receive the power from the power part 4220 and may discharge light to the optical part 4250. The light source 4240 may include the light-emitting device array including the light-emitting device according to the one or more exemplary embodiments. The light source 4240 may include light-emitting device packages 4241, a circuit board 4242, and a controller 4243. The controller 4243 may store characteristic and driving information of the light-emitting device packages 4241.

The light-emitting device packages 4241 included in the light source 4240 may be same type packages that generate light with a same wavelength. Alternatively, the light-emitting device packages 4241 may be variously configured of different packages that generate lights with different wavelengths. For example, the light-emitting device package 4241 may include a light-emitting device that emits white light by combining a yellow, green, red, or orange phosphor with a blue light-emitting device, and may include at least one of a purple light-emitting device, a blue light-emitting device, a green light-emitting device, a red light-emitting device, and an infrared light-emitting device, so that the light-emitting device package 4241 may adjust a color temperature and a CRI of the white light. Alternatively, if an LED chip emits blue light, the light-emitting device package 4241 including at least one of yellow, green, and red phosphors may emit white light of which color temperature varies according to a mixing ratio of phosphors. Alternatively, the light-emitting device package 4241 including the blue LED chip and a green or red phosphor applied thereto may emit green light or red light. The light-emitting device package 4241 that emits the white light and the light-emitting device package 4241 that emits the green or red light may be combined so as to adjust the color temperature and the CRI of the white light. Alternatively, the light-emitting device package 4241 may include at least one of a purple light-emitting device, a blue light-emitting device, a green light-emitting device, a red light-emitting device, and an infrared light-emitting device.

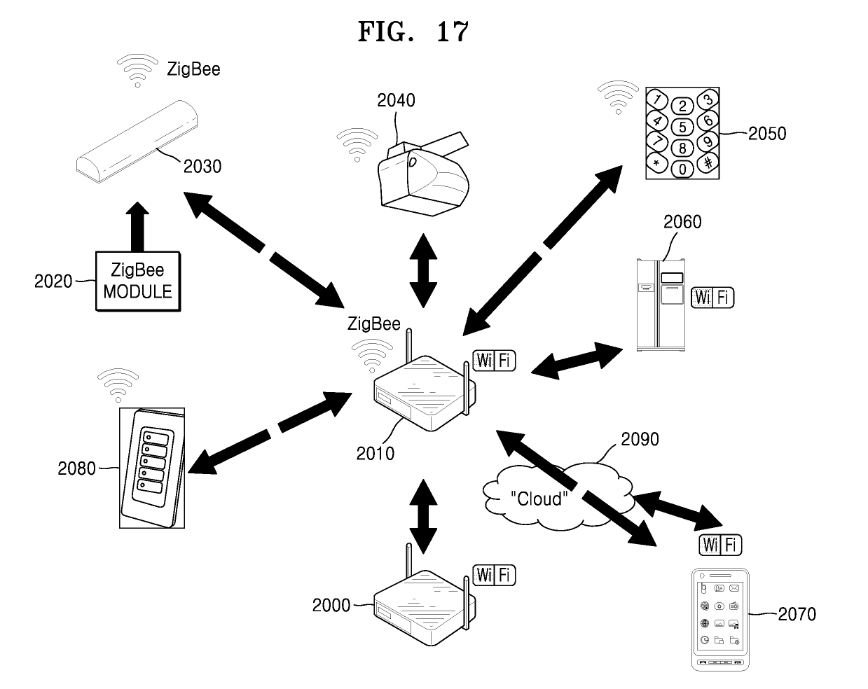

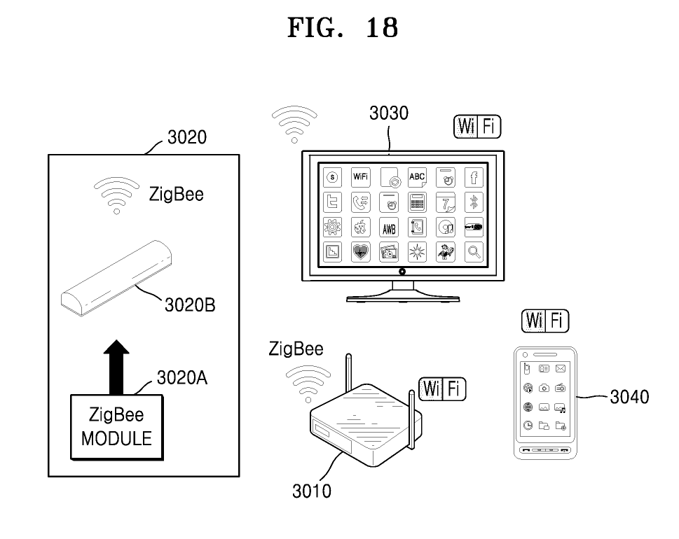

FIGS. 17 and 18 illustrate a home network to which a lighting system using a light-emitting device is applied, according to an exemplary embodiment.

As illustrated in FIG. 17, the home network may include a home wireless router 2000, a gateway hub 2010, a ZigBee module 2020, an LED lamp 2030, a garage door lock 2040, a wireless door lock 2050, home application 2060, a cell phone 2070, a wall-mounted switch 2080, and a cloud network 2090.

According to operating statuses of a bedroom, a living room, an entrance, a garage, electric home appliances, or the like and ambient environments/situations, on/off, color temperature, CRI, and/or illumination brightness of the LED lamp 2030 may be automatically adjusted by using in-house wireless communication such as ZigBee, Wi-Fi, or the like.

For example, as illustrated in FIG. 18, according to a type of a program broadcasted on a TV 3030 or brightness of a screen of the TV 3030, illumination brightness, a color temperature, and/or a CRI of an LED lamp 3020B may be automatically adjusted by using a gateway 3010 and a ZigBee module 3020A. If the program broadcasted on the TV 3030 is soap opera, illumination may be adjusted to have a color temperature equal to or less than 12,000K, e.g., a color temperature of 5,000K, and a color sense may also be adjusted according to a setting value, so that a cozy atmosphere may be created. On the other hand, if a program value indicates a comedy program, the home network may be configured so that illumination may be adjusted to have a color temperature equal to or greater than 5,000K and may have a blue-based white color, according to a setting value. Also, by using a smartphone or a computer via a home wireless communication protocol (ZigBee, WiFi, or LiFi), on/off, brightness, a color temperature, and/or a CRI of illumination, and home appliances such as the TV 3030, a refrigerator, an air conditioner, etc. that are connected to the home wireless communication protocol may be controlled. Here, the LiFi communication means a short-distance wireless communication protocol that uses visible light of illumination.

For example, the smartphone may perform an operation of executing an illumination control application program and displaying a color-coordinates system as shown in FIG. 11, and an operation of mapping, by using a ZigBee, WiFi, or LiFi communication protocol, a sensor that is connected to all illuminating apparatuses installed in a house in accordance with the chromaticity-coordinate system, i.e., an operation of displaying positions, current setting values, and on/off state values of the illuminating apparatuses in the house, an operation of selecting an illuminating apparatus at a specific position and changing a state value of the illuminating apparatus, and an operation of changing a state of the illuminating apparatus according to the changed state value, and in this manner, the illuminating apparatuses or home appliances in the house may be controlled.

The ZigBee module 2020 or 3020A may be integrally modularized with a photo sensor and also may be integrally formed with a light-emitting apparatus.

When visible-light wireless communication technology is used, information is wirelessly delivered by using light in a visible wavelength band. Differently from conventional wired optical communication technology and conventional infrared wireless communication, the visible-light wireless communication technology uses light in a visible wavelength band. Also, differently from the conventional wired optical communication technology, the visible-light wireless communication technology uses a wireless environment. Also, the visible-light wireless communication technology is highly convenient and physically secure since it is not regulated or controlled in terms of frequency usage, unlike the conventional radio frequency (RF) wireless communication, is unique since a user may check a communication link, and most of all, has a convergence characteristic by simultaneously allowing a light source to be used for its original purpose and an additional communication purpose.

Also, the LED illumination may be used as inner or outer light sources for vehicles. For the inner light sources, the LED illumination may be used as an inner light, a reading light, a gauge board, or the like for vehicles, and for the outer light sources, the LED illumination may be used as a headlight, a brake light, a direction guide light, a fog light, a daytime running light, or the like for vehicles.

An LED using a particular wavelength may promote a growth of plants, may stabilize human feelings, or may help treatment for a disease. The LED may be applied to a light source that is used in robots or various mechanical equipment. In addition to the LED having low power consumption and a long lifetime, it is possible to embody illumination of the inventive concept in combination with a nature-friendly renewable energy power system such as a solar cell system, a wind power system, or the like.

Hereinafter, test examples and comparative examples are provided to further describe configuration and effects of the inventive concept, but the scope of the inventive concept is not limited to the test examples.

### Comparative Example 1

A GaN layer was formed on a sapphire substrate by using an MOCVD method at a temperature of 1100° C.

### Experimental Example 1

A GaN layer was formed on a sapphire substrate by using an MOCVD method at a temperature of 1100° C., and then a mixture gas containing silane, ammonia, and nitrogen was supplied to the GaN layer, so that V-pits were formed. Afterward, trimethylgallium (TMGa) and ammonia were supplied to the GaN layer at a pressure of 950 mb and a temperature of 600° C., so that a mesa-shape defect decreasing structure was formed. Here, a partial pressure ratio of (ammonia)/(TMGa) was maintained at 50.

Afterward, another GaN layer was additionally formed to cover the mesa-shape defect decreasing structure, by using the MOCVD method at a temperature of 1100° C.

### Experimental Example 2

The Experimental Example 2 proceeded in the same manner as the Experimental Example 1, except that silane (SiH₄) was additionally injected to a process of forming a defect decreasing structure. A partial pressure ratio of (silane)/(TMGa) was maintained at 0.5.

Double crystal X-ray diffraction (DXRD) analysis was performed on 002 surface and 102 surface of a surface obtained from each of the Comparative Example 1, the Experimental Example 1, and the Experimental Example 2, and a relative percentage of a full width at half maximum (FWHM) of a curve of a graph obtained from the DXRD analysis was calculated. That is, when it is assumed that a FWHM with respect to the surface obtained from the Comparative Example 1 is 100, FWHM calculation results of the surfaces obtained from the Experimental Examples 1 and 2 are shown in Table 1 below.

TABLE 1

| | 002 | 102 | |
|---|---|---|---|
| | surface | surface | Remark |
| Comparative | 100 | 100 | |
| Example 1 | | | |
| Experimental | 93 | 87 | 002 surface was improved by 7%, |
| Example 1 | | | 102 surface was improved by 13% |
| Experimental | 89 | 77 | 002 surface was improved by 11%, |
| Example 2 | | | 102 surface was improved by 23% |

As shown in Table 1, the Experimental Example 1 in which the mesa-shape defect decreasing structure was formed achieved an effect of FWHM improvement by 7% and 13% for 002 surface and 102 surface, respectively, in comparison to the Comparative Example 1 in which a shape defect decreasing structure was not formed. Also, the Experimental Example 2 in which the pyramid-shape defect decreasing structure was formed achieved an effect of FWHM improvement by 11% and 23% for 002 surface and 102 surface, respectively, in comparison to the Comparative Example 1 in which a shape defect decreasing structure was not formed.

Since the FWHM was decreased, when the defect decreasing structure was formed, a TDD was decreased, and an improvement effect of a crystal quality of the surface was achieved.

Also, the TDD was measured on the surface of the Experimental Example 2 and the surface of the Comparative Example 1, by performing cathode luminescence (CL) analysis. In more detail, the CL analysis was performed by measuring an emission quality from 300 nm to 800 nm by using an FEI's environmental scanning electron microscope (ESEM) with CL measuring equipment.

As a result, it is apparent that the TDD of the surface obtained from the Experimental Example 2 was decreased by 43%, compared to the surface obtained from the Comparative Example 1.

As described above, by using the method of manufacturing a semiconductor light-emitting device according to the one or more exemplary embodiments, the excellent-quality semiconductor light-emitting device having a reduced crystal defect may be inexpensively manufactured.

While the inventive concept has been particularly shown and described with reference to exemplary embodiments thereof, it will be understood that various changes in form and details may be made therein without departing from the spirit and scope of the following claims.

What is claimed is:

1. A method of manufacturing a semiconductor light-emitting device, the method comprising:
forming a first conductive type semiconductor layer on a substrate;
forming a V-pit in the first conductive type semiconductor layer;
forming a defect decreasing structure in and over the V-pit; and
forming a residual first conductive type semiconductor layer on the defect decreasing structure.

2. The method of claim 1, wherein the defect decreasing structure is a mesa-shape structure or a pyramid-shape structure.

3. The method of claim 2, wherein, when the defect decreasing structure is the pyramid-shape structure, the pyramid-shape structure comprises silicon (Si).

4. The method of claim 3, wherein a density of Si in the pyramid-shape structure is 5×10¹⁷ cm⁻³ through 1×10²⁰ cm⁻³.

5. The method of claim 1, wherein the forming of the defect decreasing structure comprises supplying a group-III source material and a group-V source material and the forming of the defect decreasing structure is performed under at least one condition of (i) a higher pressure, (ii) a higher growth rate of the defect decreasing structure, and (iii) a lower (group-V source material)/(group-III source material) molar ratio, compared to the forming of the first conductive type semiconductor layer that is performed before the forming of the defect decreasing structure.

6. The method of claim 5, wherein (i) the higher pressure is a pressure of 70 millibars (mb) through 1 atmosphere (atm).

7. The method of claim 5, wherein (ii) the higher growth rate is a growth rate of 1.5 Å/sec. through 85 Å/sec.

8. The method of claim 5, wherein (iii) the lower (group-V source material)/(group-III source material) molar ratio is 20 through 400.

9. The method of claim 1, wherein the first conductive type semiconductor layer is a group III-V semiconductor layer,
wherein forming the first conductive type semiconductor layer comprises:
supplying a group-III source material and a group-V source material onto the substrate, and
forming the V-pit comprises:
stopping supplying the group-III source material to the first conductive type semiconductor layer; and
supplying a silicon (Si) source material to the first conductive type semiconductor layer.

10. The method of claim 1, further comprising, after the forming of the residual first conductive type semiconductor layer,
forming an active layer on the residual first conductive type semiconductor layer; and
forming a second conductive type semiconductor layer on the active layer.

11. A method of manufacturing a semiconductor light-emitting device, the method comprising:
supplying a group-III source material and a group-V source material onto a substrate so as to form a first conductive type semiconductor layer on the substrate;
stopping supplying the group-III source material, and supplying a silicon (Si) source material so as to form a V-pit in the first conductive type semiconductor layer;
supplying the group-III source material and the group-V source material to the V-pit so as to form a defect decreasing structure in and over the V-pit; and
supplying the group-III source material and the group-V source material so as to form a residual first conductive type semiconductor layer on the defect decreasing structure.

12. The method of claim 11, wherein the supplying of the group-III source material and the group-V source material so as to form the defect decreasing structure in the V-pit comprises supplying the group-III source material and the group-V source material without supplying the silicon (Si) source material so as to form a mesa-shape defect decreasing structure.

13. The method of claim 11, wherein the supplying of the group-III source material and the group-V source material so as to form the defect decreasing structure in the V-pit comprises supplying the silicon (Si) source material so as to form a pyramid-shape defect decreasing structure.

14. The method of claim 11, wherein the silicon (Si) source material is silane (SiH₄).

15. The method of claim 11, wherein, in the supplying of the group-III source material so as to form the defect decreasing structure in the V-pit, the group-III source material is at least one material selected from the group consisting of an aluminum (Al) source material, an indium (In) source material, and a gallium (Ga) source material.

16. A method of manufacturing a semiconductor light-emitting device, the method comprising:
forming a first conductive type semiconductor layer on a substrate;
forming a plurality of V-pits in a top surface of the first conductive type semiconductor layer wherein each of the plurality of V-pits has a first slope;
forming a plurality of defect decreasing structures in corresponding ones of the plurality of V-pits such that each of the plurality of defect decreasing structures above the top surface of the first conductive type semiconductor layer has a second slope different from the first slope of a corresponding one of the plurality of V-pits; and
forming a residual first conductive type semiconductor layer on the plurality of defect decreasing structures.

17. The method of claim 16, wherein the plurality of the V-pits are separated from each other or partially overlapped with each other.

18. The method of claim 16, wherein the plurality of defect decreasing structures have a composition of AlₓIn_{y}Ga_{(1-x-y)}N (0≦x≦1, 0≦y≦1, 0≦x+y≦1) and forming the plurality of defect decreasing structures includes supplying a group-III source material and a group-V source material.

19. The method of claim 18, wherein the plurality of defect decreasing structures are formed under a condition where one of a pressure, a growth rate of the plurality of defect decreasing structures and a molar ratio of (group-V source material)/(group-III source material) is different from that in the forming the first conductive type semiconductor layer.

20. The method of claim 16, wherein each of the first conductive type semiconductor layer and the residual first conductive type semiconductor layer has a thickness of 10 nm through 5000 nm.
